(19) United States
(12) Patent Application Publication
(10) Pub. No.: US 2026/0032958 A1
(43) Pub. Date: Jan. 29, 2026

(54) Bottom Isolations and Methods of Forming Same

(71) Applicant: Taiwan Semiconductor Manufacturing Company, Ltd., Hsin-Chu (TW)

(72) Inventors: Ta-Chun LIN, Hsinchu (TW); Jhon Jhy LIAW, Hsinchu County (TW)

(21) Appl. No.: 18/783,831

(22) Filed: Jul. 25, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 62/151; H10D 64/017; H10D 64/018; H10D 84/013; H10D 84/0135; H10D 84/0149; H10D 84/0151; H10D 84/038; H10D 84/83

(57) ABSTRACT

A semiconductor structure includes a fin-shaped structure protruding from a substrate and including a fin base and a stack of channel layers over the fin base, an isolation feature disposed adjacent to the fin base, a first dielectric layer disposed over the isolation feature, a metal gate structure wrapping around the stack of channel layers, a gate spacer disposed over the isolation feature and along a sidewall of the metal gate structure, a second dielectric layer disposed over the fin base and adjacent to the stack of channel layers, and a source/drain feature disposed over the second dielectric layer and connected to the stack of channel layers. The metal gate structure and the gate spacer are disposed over a portion of the first dielectric layer. From a top view, the first dielectric layer and the second dielectric layer form a checkerboard pattern or a strip network pattern.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, parasitic capacitance and current leakage (e.g., from a mesa) may have serious bearings on the overall performance of an IC device. While existing techniques are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2A, 3A, 4A, 5A, 7A, 8A, 9A, 10A, 11A, 12A, 13A, 14A, 15A, 16A, 17A, and 18 illustrate fragmentary top views of an exemplary semiconductor structure during various fabrication stages in the method of FIG. 1, according to one or more aspects of the present disclosure.

FIGS. 2B, 3B, 3C, 4B, 5B, 9B, 10B, 13B, and 17B illustrate fragmentary cross-sectional views of the semiconductor structure taken along line A-A as shown in FIGS. 2A, 3A, 3A, 4A, 5A, 9A, 10A, 13A, and 17A, respectively, according to one or more aspects of the present disclosure.

FIGS. 2C, 4C, 5C, 6, 7B, 7D, 8B, 9C, and 10C illustrate fragmentary cross-sectional views of the semiconductor structure taken along line B-B as shown in FIGS. 2A, 4A, 5A, 5A, 7A, 7A, 8A, 9A, and 10A, respectively, according to one or more aspects of the present disclosure.

FIGS. 2D, 3D, 4D, 5D, 8C, 9D, 10D, 11B, 13C, and 17C illustrate fragmentary cross-sectional views of the semiconductor structure taken along line C-C as shown in FIGS. 2A, 3A, 4A, 5A, 8A, 9A, 10A, 11A, 13A, and 17A, respectively, according to one or more aspects of the present disclosure.

FIGS. 4E, 5E, 7C, 7E, 8D, 9E, 10E, 11C, 12B, 13D, 14B, 15B, and 16B illustrate fragmentary cross-sectional views of the semiconductor structure taken along line D-D as shown in FIGS. 4A, 5A, 7A, 7A, 8A, 9A, 10A, 11A, 12A, 13A, 14A, 15A, and 16A, respectively, according to one or more aspects of the present disclosure.

FIG. 9F illustrates a graph of levels of surfaces in the semiconductor structure, according to one or more aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor. Parasitic capacitance and current leakage may impact the overall performance of a multi-gate device. Isolation feature loss during manufacturing may result in deep gate structure, which may have parasitic capacitance. While existing techniques are generally adequate for their intended purposes, they are not satisfactory in all aspects.

The present disclosure provides various embodiments of a semiconductor structure. Particularly, the semiconductor structure includes a multi-gate device, such as a FinFET transistor or a GAA transistor. The semiconductor structure includes fin-like structures, isolation features between two adjacent fin-like structures, and bottom isolation features including a first dielectric layer and a second dielectric layer. The first dielectric layer may be disposed over the isolation features, and below a gate spacer or below both a gate structure and a gate spacer. The second dielectric layer may be disposed between source/drain features and a fin base of the fin-like structures. In some embodiments, from a top view, the bottom isolation features form a pattern, such as a checkerboard pattern or a strip network pattern. By having the bottom isolation features, parasitic capacitance and current leakage from the fin base may be mitigated, isolation feature lost during manufacturing may be reduced or avoided, and parasitic capacitance from deep gate structures may be reduced or avoided.

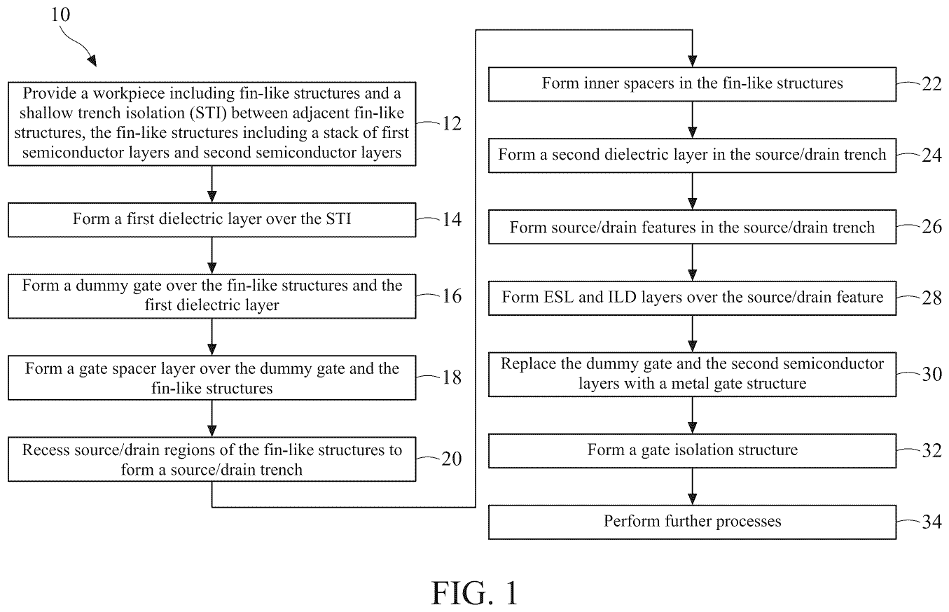

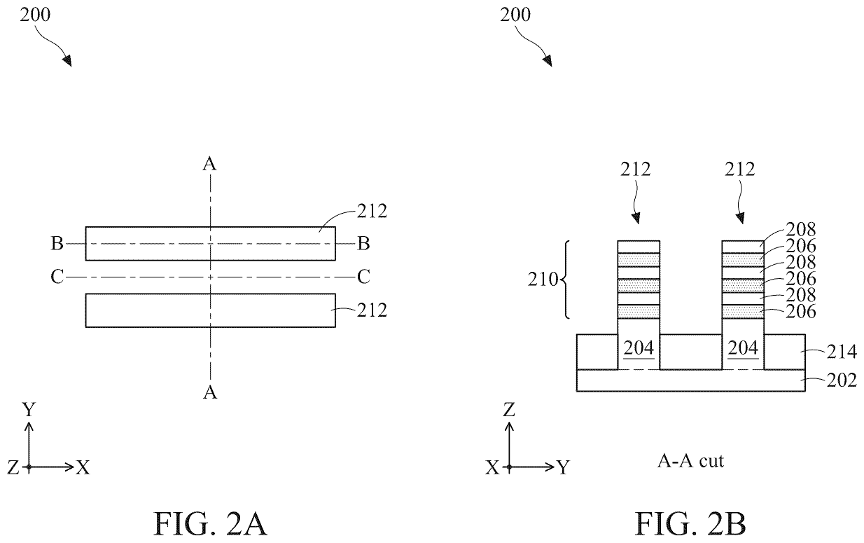

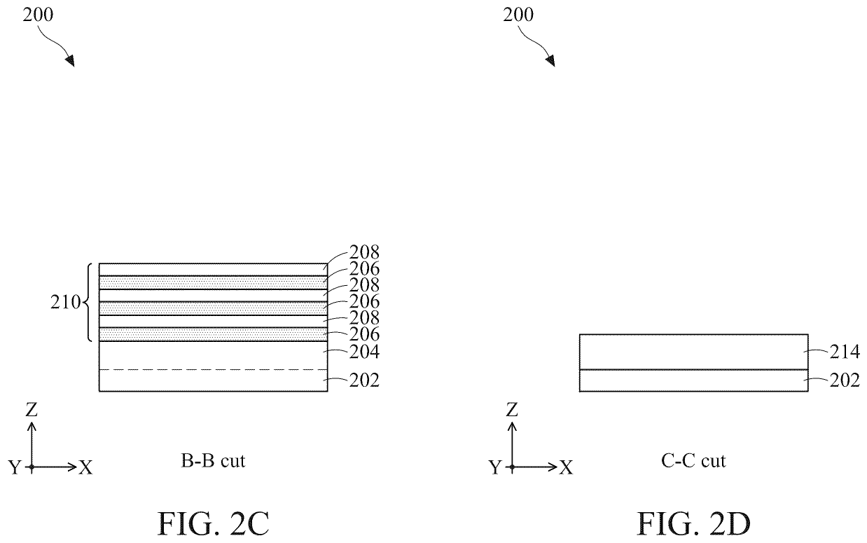

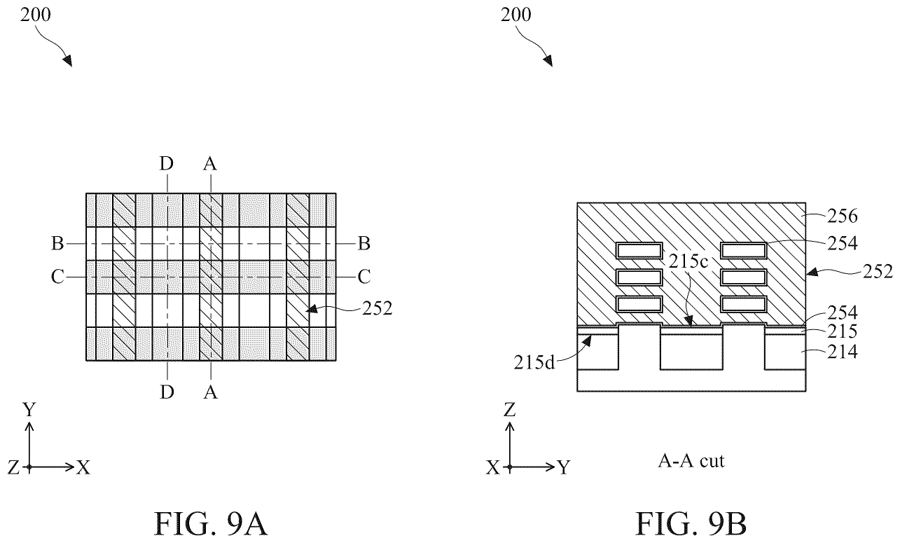

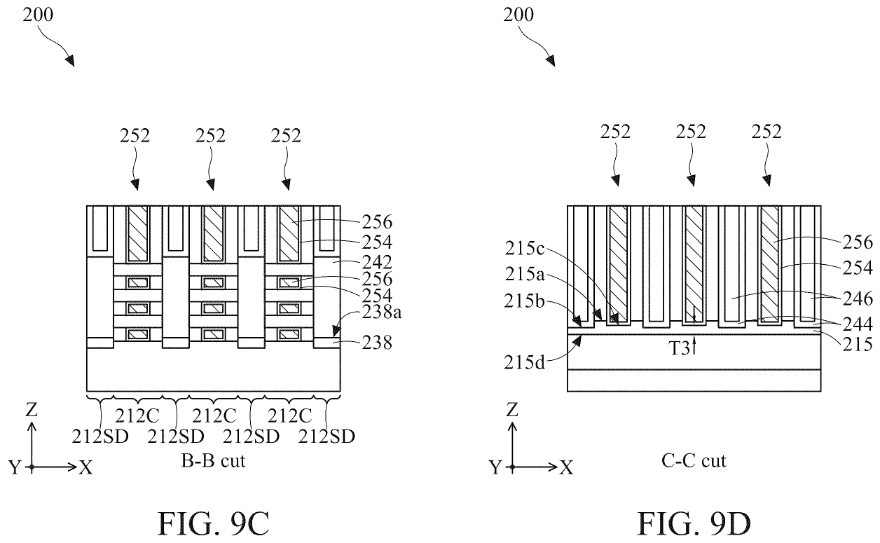

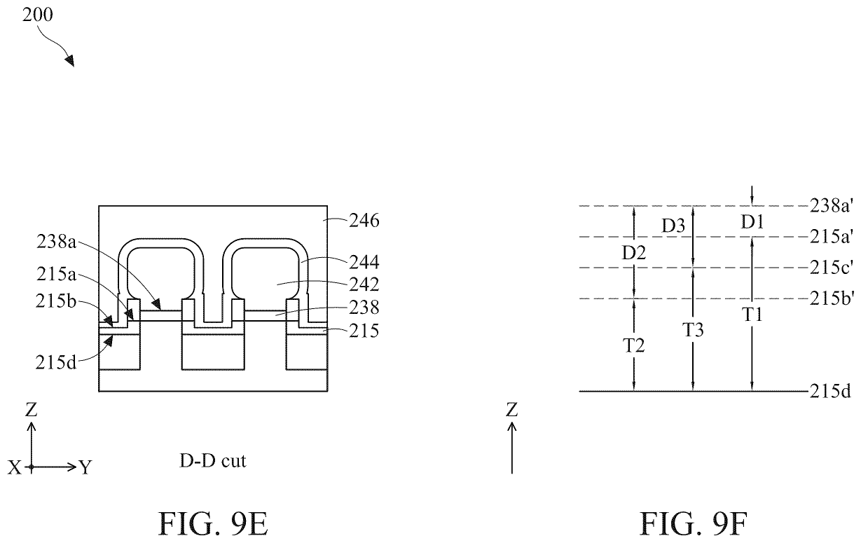

The various aspects of the present disclosure will now be described in more detail with reference to the figures. In that regard, FIG. 1 is a flowchart illustrating method 10 of forming a semiconductor structure according to embodiments of the present disclosure. Method 10 is described below in conjunction with FIGS. 2A-18. FIGS. 2A-9E and 10A-18 are fragmentary top/cross-sectional views of a workpiece 200 at different stages of fabrication according to embodiments of method 10. FIG. 9F is a graph showing levels of surfaces of the workpiece 200. Some of the operations may only be briefly described herein. Upon conclusion of the operations of method 10, the workpiece 200 will be fabricated into a semiconductor device 200. In that sense, the workpiece 200 may be referred to as a semiconductor structure 200 or a semiconductor device 200 as the context requires. Further, the semiconductor structure may include various other devices and features, such as other types of devices including additional transistors, bipolar junction transistors, resistors, capacitors, inductors, diodes, fuses, SRAM and/or other logic circuits, etc., but is simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected. Moreover, it is noted that the process steps of method 10, including any descriptions given with reference to FIGS. 2A-18, as with the remainder of the method and exemplary figures provided in this disclosure, are merely exemplary and are not intended to be limiting beyond what is specifically recited in the claims that follow. Additional steps may be provided before, during and after the method 10, and some steps described can be replaced, eliminated, or moved around for additional embodiments of the method. For avoidance of doubts, the X, Y and Z directions in FIGS. 2A-18 are perpendicular to one another and are used consistently throughout the present disclosure. Throughout the present disclosure, like reference numerals denote like features unless otherwise excepted.

Referring to FIGS. 1 and 2A-2D, method 10 includes a block 12 where a workpiece 200 is received or provided. FIG. 2A depicts a fragmentary top view of the workpiece 200 to undergo various stages of operations in the method 10 of FIG. 1, according to various aspects of the present disclosure. FIGS. 2B, 2C, and 2D illustrate fragmentary cross-sectional views of the workpiece 200 taken along line A-A, B-B, C-C, as shown in FIG. 2A, respectively.

The workpiece 200 includes a substrate 202, which may be a semiconductor substrate such as a silicon substrate. The substrate 202 may include various layers, including conductive or insulating layers formed on a semiconductor substrate. The substrate 202 may include various doping configurations depending on design requirements as is known in the art. For example, different doping profiles (e.g., n-wells, p-wells) may be formed on the substrate 202 in regions designed for different device types (e.g., n-type GAA transistors, p-type GAA transistors). The suitable doping may include ion implantation of dopants and/or diffusion processes. The substrate 202 may also include other semiconductors such as germanium, silicon carbide (SiC), silicon germanium (SiGe), or diamond. Alternatively, the substrate 202 may include a compound semiconductor and/or an alloy semiconductor. In an embodiment of the method 100, an anti-punch through (APT) implant is performed. The APT implant may be performed in a region underlying the channel region of a device for example, to prevent punch-through or unwanted diffusion.

The workpiece 200 includes a number of fin-shaped active regions 212 (also referred to as fin-shaped structures 212 or fin-like structures 212) protruding from the substrate 202. The number of fin-shaped active regions 212 depicted in FIG. 2A is merely exemplary, the workpiece 200 may include any suitable number of active regions 212. Each of the fin-shaped active regions 212 may include a fin base 204 (also referred to as a mesa 204) and a semiconductor layer stack 210 of alternating semiconductor layers disposed over the fin base 204. In an embodiment, the semiconductor layer stack 210 includes a number of channel layers 208 (or semiconductor layers 208) interleaved by a number of sacrificial layers 206 (or semiconductor layers 206). Each of the semiconductor layers 208 and 206 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). Although the semiconductor layer stack 210 of the depicted example includes three channel layers 208 and three sacrificial layers 206, it is understood that the semiconductor layer stack 210 may include any suitable number (e.g., 2 to 10) of channel layers and any suitable number of sacrificial layers.

The layers in the semiconductor layer stack 210 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the semiconductor layer stack 210.

The fin-shaped structure 212 may be formed from the deposited layers of the semiconductor layer stack 210 and the substrate 202. A hard mask layer may be deposited over the deposited layers of the semiconductor layer stack 210 to form an etch mask. The hard mask layer may be a single layer or a multi-layer. For example, the hard mask layer may include a pad oxide layer and a pad nitride layer over the pad oxide layer. The fin-shaped structure 212 may be patterned from the deposited layers of the semiconductor layer stack 210 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. The etch process forms trenches extending through the semiconductor layer stack 210 and extending through a portion of the substrate 202 to form the fin base 204. The trenches define the fin-shaped structure 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the deposited layers of the semiconductor layer stack 210. As shown in FIGS. 2A-2C, the fin-shaped structure 212, along with the sacrificial layers 206 and the channel layers 208 therein, extends vertically along the Z direction and lengthwise along the X direction.

The workpiece 200 may include isolation features 214 adjacent the fin-shaped structure 212. In some embodiments, the isolation features 214 may be formed in the trenches to isolate the fin-shaped structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation feature 214. The fin-shaped structure 212 rises above the isolation feature 214 after the recessing.

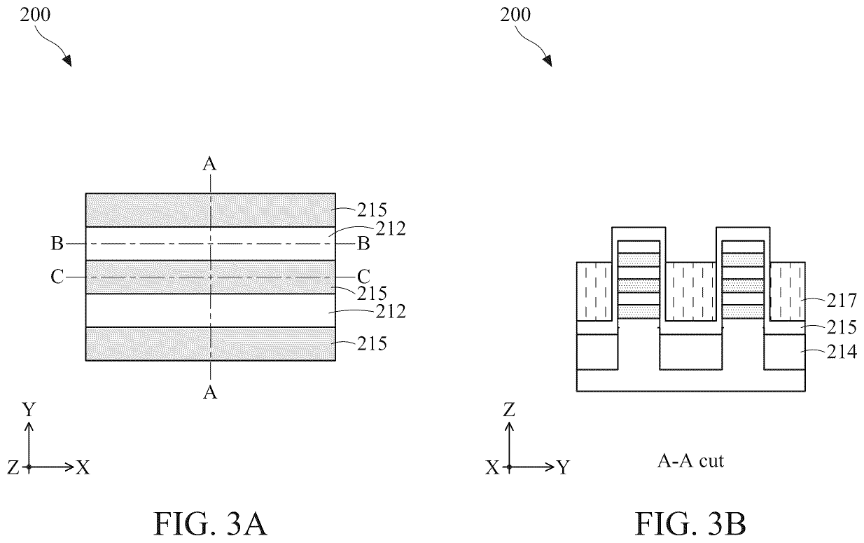

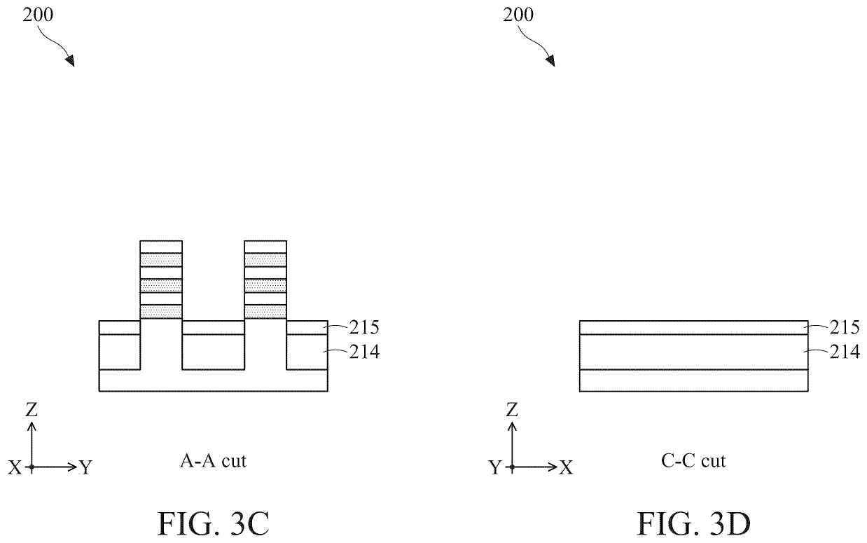

Referring to FIGS. 1 and 3A-3D, method 10 includes a block 14 where a first dielectric layer 215 is formed over the isolation feature 214. FIG. 3A depicts a fragmentary top view of the workpiece 200. FIG. 3B illustrates a fragmentary cross-sectional view of the workpiece 200 taken along line A-A as in FIG. 3A at an intermediate stage in block 14. FIGS. 3C-3D illustrate fragmentary cross-sectional views of the workpiece 200 after operations in block 14 taken along line A-A and C-C, as shown in FIG. 3A, respectively.

Referring to FIG. 3B, block 14 includes operations where the first dielectric layer 215 is deposited over the workpiece 200. The first dielectric layer 215 may be a single layer or multi-layers. In some embodiments, the first dielectric layer 215 includes silicon nitride (SiN), silicon oxycarbonitride (SiCON), silicon oxide, silicon carbonitride (SiCN), silicon oxynitride (SiON), silicon oxycarbide (SiCO), a high-k dielectric material, or a combination thereof. A high-k dielectric material includes materials such as hafnium oxide, titanium oxide (TiO₂), hafnium zirconium oxide (HfZrO), tantalum oxide (Ta₂O₅), hafnium silicon oxide (HfSiO4), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO). In one embodiment, the first dielectric layer 215 includes silicon nitride.

The first dielectric layer 215 is deposited over top surfaces (or top-facing surfaces) of the isolation features 214, sidewalls of the fin-shaped structures 212, and top surfaces (or top-facing surfaces) of the fin-shaped structures 212 using chemical vapor deposition (CVD) or physical vapor deposition (PVD). Because the top-facing surfaces are more in the line of sight, the first dielectric layer 215 over the top-facing surfaces is thicker than the first dielectric layer 215 disposed along sidewalls of the fin-shaped structures 212 as in FIG. 3B.

A bottom antireflective coating (BARC) layer 217 is then deposited over the first dielectric layer 215. In some implementations, the BARC layer 217 may include silicon oxynitride (SiON), silicon oxycarbide, a polymer, or other suitable materials. The BARC layer 217 and the first dielectric layer 215 may include different compositions. In some implementations, the BARC layer 218 may be deposited over the first dielectric layer 215 using CVD, spin-on processes, or other suitable processes. After the deposition of the BARC layer 217, it is etched back to expose a portion of the first dielectric layer 215 as depicted in FIG. 2B. The etching back may include use of a dry etch process. The dry etch process may include use of plasma of argon (Ar), oxygen (O₂), nitrogen (N₂), hydrogen (H₂), or a combination thereof.

Then, the first dielectric layer 215 not covered by the BARC layer 218 is trimmed. In some embodiments, the trimming may include use of an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The trimming exposes at least a portion of the topmost channel layers 208.

Referring to FIG. 3C, the rest of the BARC layer 217 may be removed using an ashing process or a dry etch process that includes use of plasma of argon (Ar), oxygen (O₂), nitrogen (N₂), hydrogen (H₂), or a combination thereof. The first dielectric layer 215 over sidewalls of the fin-shaped structure 212 is removed. In some embodiments, an isotropic process, such as a wet etch process, is used at block 14. An example wet etch process may include use of a warm phosphoric acid (H₃PO₄). As described above, because the first dielectric layer 215 along the sidewalls of the fin-shaped structures 212 are thinner than the counterpart over the isolation feature 214, the first dielectric layer 215 along the sidewalls of the fin-shaped structures 212 may be completely removed while a portion of the first dielectric layer 215 over the isolation feature 214 remains.

Referring to FIGS. 3A and 3C-3D, in some implementations, after operations of block 14, the first dielectric layer 215 is disposed on top surfaces of the isolation features 214. In some embodiments, a thickness of the first dielectric layer 215 may be between about 6 nm and about 25 nm.

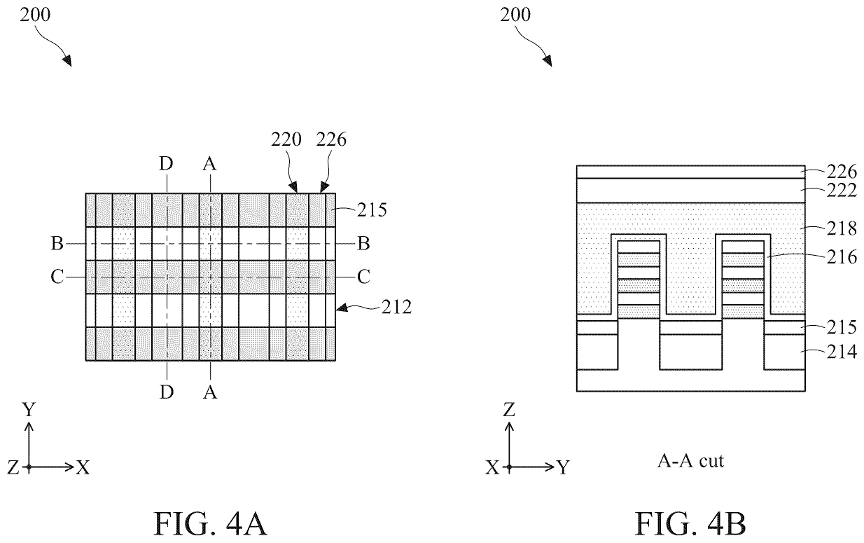

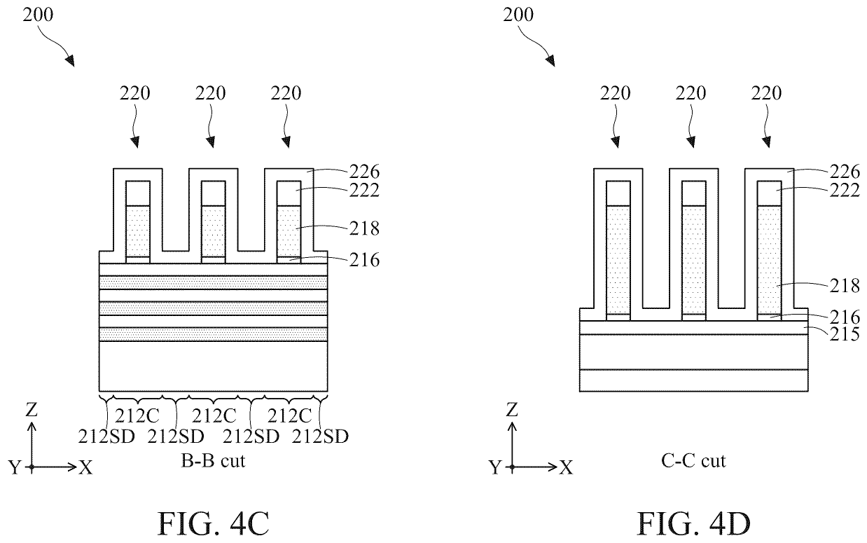

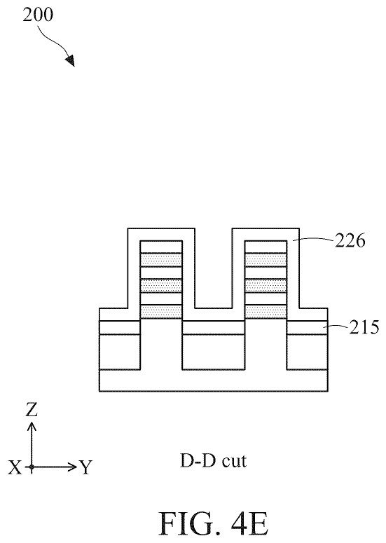

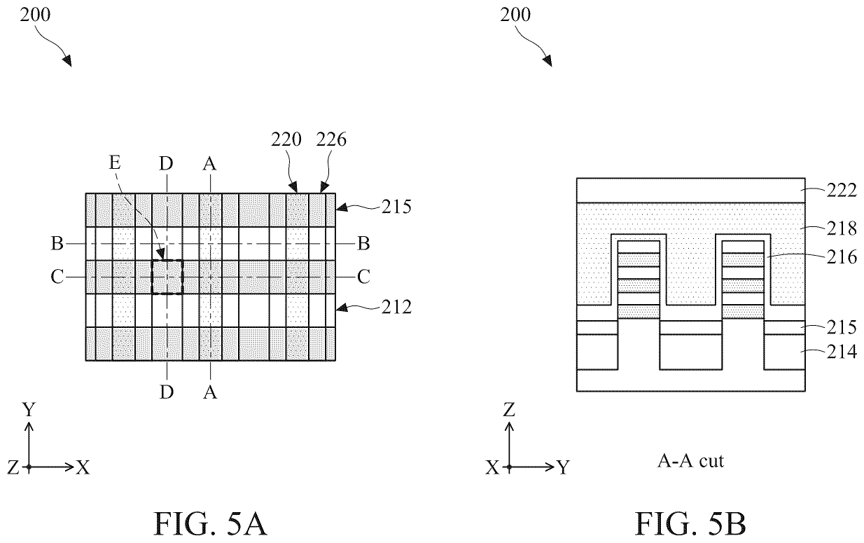

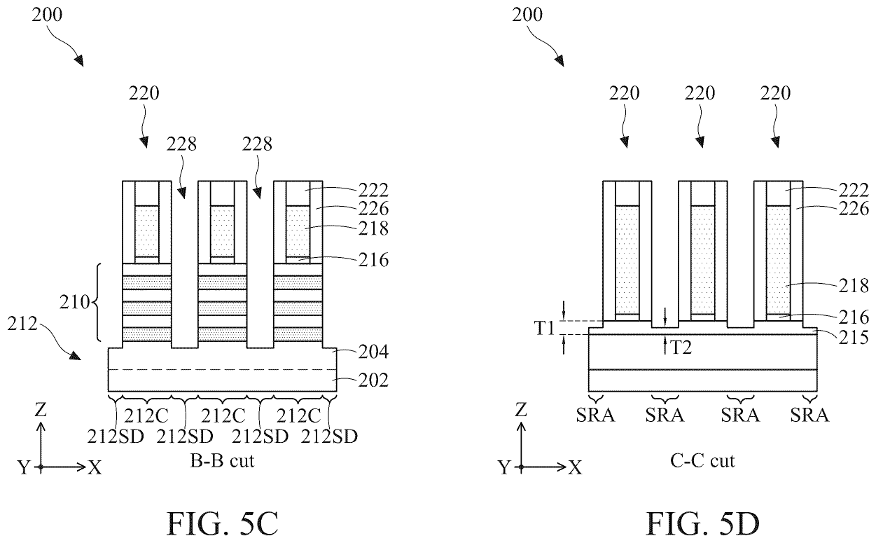

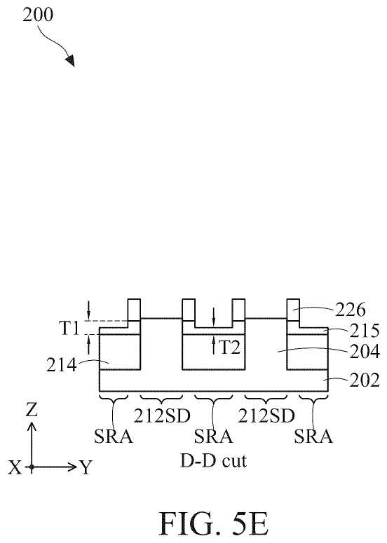

Referring to FIGS. 1 and 4A-4E, method 10 includes a block 16 where a dummy gate 220 is formed over a channel region 212C of the fin-shaped structures 212. FIG. 4A depicts a fragmentary top view of the workpiece 200. FIGS. 4B-4E illustrate fragmentary cross-sectional views of the workpiece 200 taken along line A-A, B-B, C-C, and D-D, as shown in FIG. 4A, respectively. The numbers of the dummy gate stacks 220 shown in FIGS. 4A-4E are for illustration purpose only and should not be construed as limiting the scope of the present disclosure. It is noted that the first dielectric layer 215 in FIG. 4A shows its position from a top view, and portions of the first dielectric layer 215 overlapping with features (e.g., the dummy gate 220) may be below the features. This also applies to the first dielectric layer 215 in FIGS. 5A, 7A, 8A, 9A, 10A, 11A, 12A, 13A, and 14A.

In some embodiments, a gate replacement process (or gate-last process) is adopted where the dummy gate stack 220 serves as a placeholder to undergo various processes and is to be removed and replaced by the functional metal gate structure. Other processes and configuration are possible. In some embodiments, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 4C, the channel region 212C is disposed between two source/drain regions 212SD along the X-direction.

The formation of the dummy gate stack 220 may include forming layers in the dummy gate stack 220 and patterning these layers. Referring to FIGS. 4B-4D, a dummy dielectric layer 216, a dummy electrode layer 218, and a gate-top hard mask layer 222 may be blanketly formed over the workpiece 200. In the illustrated embodiment, the dummy dielectric layer 216 is formed on the top and sidewall surfaces of the semiconductor layer stack 210 and over the top surfaces of the first dielectric layer 215. In an alternative embodiment not depicted, the dummy dielectric layer 216 is formed as a blanket layer over the top and sidewall surfaces of the semiconductor layer stack 210 but not on the top surfaces of the first dielectric layer 215. The dummy dielectric layer 216 may provide protection to the semiconductor layer stack 210. The dummy dielectric layer 216 may be formed by various methods such as chemical oxidation of silicon, thermal oxidation of silicon, ozone oxidation of silicon, atomic layer deposition (ALD), chemical vapor deposition (CVD), physical vapor deposition (PVD), or other suitable methods. The dummy dielectric layer 216 may include silicon oxide.

Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stacks 220, as shown in FIGS. 4B-4D. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer and a silicon nitride layer (not depicted) over the silicon oxide layer. As shown in FIG. 4C, the dummy gate stack 220 is patterned such that it is only disposed over the channel region 212C, not disposed over the source/drain region 212SD.

Still referring to FIGS. 1 and 4A-4E, method 10 includes a block 18 where a gate spacer layer 226 is deposited over the workpiece 200, including the dummy gate stack 220. In some embodiments, the gate spacer layer 226 is deposited conformally over the workpiece 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

Referring to FIGS. 1 and 5A-5E, method 10 includes a block 20 where a source/drain region 212SD of the fin-shaped structure 212 is anisotropically recessed to form source/drain trenches 228. FIG. 5A depicts a fragmentary top view of the workpiece 200. FIGS. 5B, 5C, 5D, and 5E illustrate fragmentary cross-sectional views of the workpiece 200 taken along line A-A, B-B, C-C, and D-D, as shown in FIG. 5A, respectively.

The anisotropic etch may include a dry etch or a suitable etch process that etches the source/drain regions 212SD and the gate spacer layer 226 thereover. An example dry etch process for block 20 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Referring to FIG. 5C, the resulting source/drain trenches 228 extend vertically through the depth of the semiconductor layer stack 210 and partially into the fin base 204. In some embodiments, the source/drain regions 212SD of the fin-shaped structure 212 are recessed to expose sidewalls of the sacrificial layers 206 and the channel layers 208. Because the source/drain trenches 228 extend below the semiconductor layer stack 210 into the fin base 204, the source/drain trenches 228 include bottom surfaces and lower sidewalls defined in the fin base 204.

Referring to FIG. 5E, over the source/drain regions 212SD, the majority of the fin-shaped structure 212 is etched away and a top surface of the fin base 204 is exposed in the source/drain region 212SD. Because the gate spacer layer 226 is etched at a slower rate than the fin-shaped structure 212, after operations of block 20, a portion of the gate spacer layer 226 adjacent to the source/drain region 212SD (the portion is also referred to as a fin side spacer 226) as in FIG. 5E rises above the top surface of the fin base 204. It is noted that the fin side spacer 226 is omitted in the depicted fragmentary top views (e.g., in FIG. 5A) for the purpose of simplicity. In some instances, a top surface of the first dielectric layer 215 under the gate spacer layer 226 may also be higher than the top surface of the fin base 204 in the source/drain region 212SD.

Referring to FIGS. 5A, 5D, and 5E, in some embodiments, the anisotropic etch removes top portions of the first dielectric layer 215 in areas (e.g., area E in FIG. 5A) between opposing gate spacer layers 226 along the X-direction and between opposing fin side spacers 226 along the Y-direction. For simplicity, such areas may also be referred to as source/drain region areas (SRA). Thus, a top surface of the first dielectric layer 215 in the source/drain region areas SRA is lower than a top surface of the first dielectric layer 215 below the gate spacer layer 226 and below the dummy gate stacks 220. In some embodiments, the first dielectric layer 215 has a first thickness T1 below the gate spacer layer 226 and below the dummy gate stacks 220, and has a second thickness T2 in the source/drain region areas SRA. In some embodiments, T1 is greater than T2 by about 1 nm to about 5 nm.

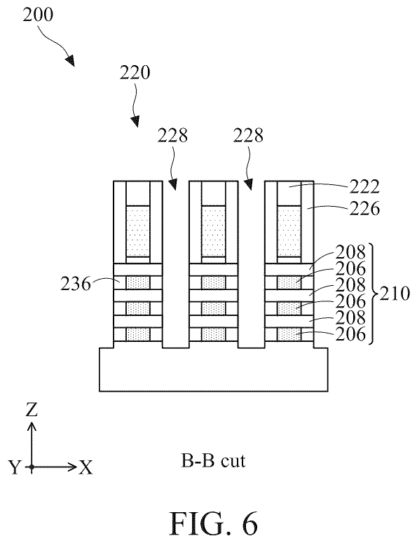

Referring to FIGS. 1 and 6, method 10 includes a block 22 where inner spacers are formed in the semiconductor layer stack 210. A fragmentary top view of the workpiece 200 at block 22 is similar to FIG. 5A. FIG. 6 illustrates a fragmentary cross-sectional view of the workpiece 200 taken along line B-B as shown in FIG. 5A.

At block 22, inner spacer recesses (not depicted) are selectively formed in the semiconductor layer stacks 210. As described above, a composition of the semiconductor layers 208 is different from that of the sacrificial layers 206. At block 22, the different compositions allow the sacrificial layers 206 in the semiconductor layer stacks 210 exposed in the source/drain recesses 228 to be selectively and partially recessed to form inner spacer recesses while the exposed semiconductor layers 208 are substantially unetched. In an embodiment where the semiconductor layers 208 consist essentially of Si and sacrificial layers 206 consist essentially of SiGe, the selective recess of the sacrificial layers 206 may include a SiGe oxidation process followed by a SiGe oxide removal. In those embodiments, the SiGe oxidation process may include use of ozone. In some embodiments, the selective recess may be a selective isotropic etching process (e.g., a selective dry etching process or a selective wet etching process), and the extent the sacrificial layers 206 are recessed is controlled by duration of the etching process. In some embodiments, the selective dry etching process may include use of one or more fluorine-based etchants, such as fluorine gas or hydrofluorocarbons. The inner spacer recesses may extend inward along the Y-direction from the source/drain recesses 228. In some embodiments, the selective wet etching process may include a hydro fluoride (HF) or NH₄OH etchant.

Then, inner spacers 236 as shown in FIG. 6 are formed in the inner spacer recesses. In some embodiments, an inner spacer layer may be deposited over the workpiece 200 by CVD, PECVD, low-pressure CVD (LPCVD), ALD or other suitable method. The inner spacer layer may be formed of aluminum oxide, zirconium oxide, tantalum oxide, yttrium oxide, titanium oxide, lanthanum oxide, silicon oxide, silicon carbonitride, silicon oxycarbonitride, silicon oxycarbide, low-k material, other suitable metal oxide, or a combination thereof. In some implementations, the inner spacer layer may be deposited conformally over the top surface of the gate-top hard mask layer 222, top surfaces and sidewalls of the gate spacer layer 226, portions of the fin base 204 exposed in the source/drain recesses 228, and top surfaces of the first dielectric layer 215. Subsequently, as shown in FIG. 6, the deposited inner spacer layer may be etched back to form inner spacers 236 in the inner spacer recesses. In the etch back process, the inner spacer layer outside the inner spacer recesses is removed. Side surface of the inner spacers 236 may not be flush with sidewalls of the semiconductor layers 208.

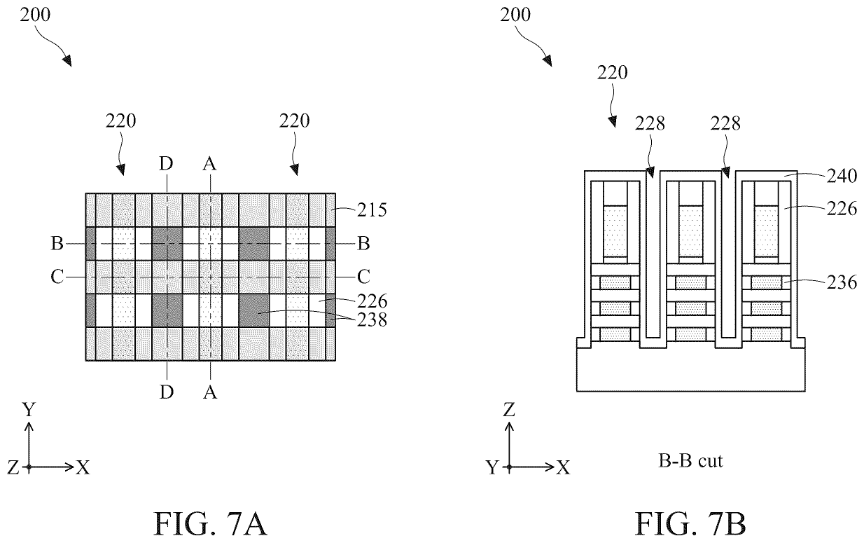

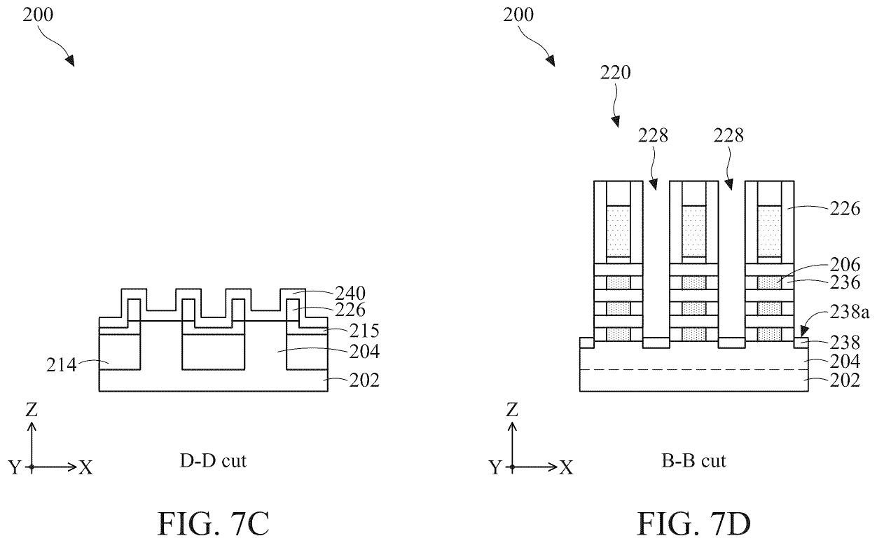

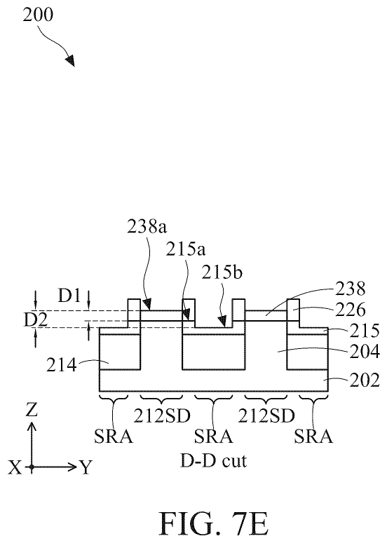

Referring to FIGS. 1 and 7A-7E, method 10 includes a block 24 where a second dielectric layer 238 is formed in the source/drain trenches 228. FIG. 7A depicts a fragmentary top view of the workpiece 200. FIGS. 7B and 7C illustrate fragmentary cross-sectional views of the workpiece 200 at an intermediate stage in block 24 taken along line B-B and D-D, as shown in FIG. 7A, respectively. FIGS. 7D and 7E illustrate fragmentary cross-sectional views of the workpiece 200 after operations in block 24 taken along line B-B and D-D, as shown in FIG. 7A, respectively.

In some embodiments, the second dielectric layer 238 is formed in the bottom of the source/drain trenches 228. Operation at block 24 may include deposition of a dielectric material 240 over the workpiece 200, and etch back the dielectric material 240 to form the second dielectric layer 238 in the bottom of the source/drain trenches 228. The second dielectric layer 238 provides isolation on a top surface of the mesa 204, thus may reduce and/or avoid parasitic capacitance and current leakage from the mesa 204. In some embodiments, the dielectric material 240 includes silicon oxide, silicon oxycarbonitride, silicon nitride, silicon carbonitride (SiCN), carbon-rich silicon carbonitride, silicon oxynitride (SiON), silicon oxycarbide (SiCO), a metal nitride (e.g., ZrN, AlON, TaCN), a high-k dielectric material, or a combination thereof. A high-k dielectric material includes materials such as hafnium oxide, titanium oxide (TiO₂), hafnium zirconium oxide (HfZrO), tantalum oxide (Ta₂O₅), hafnium silicon oxide (HfSiO4), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO). In some embodiments, the dielectric material 240 includes silicon oxynitride. In some embodiments, the dielectric material 240, the first dielectric layer 215, the isolation feature 214, and the gate spacer layer 226 have different compositions. In an example, the dielectric material 240 includes silicon oxynitride, the first dielectric layer 215 includes silicon nitride, and the isolation feature 214 includes silicon oxide.

Referring to FIGS. 7B and 7C, the dielectric material 240 is deposited over the workpiece 200, including over sidewalls and bottom surfaces of the source/drain trenches 228 and over sidewalls and top surfaces of the dummy gate stacks 220. In some implementations, the dielectric material 240 may be deposited using a directional deposition process, such as PEALD with RF plasma treatment, or other suitable methods. Under the directional plasma treatment, the horizontal portion of the dielectric material 240 receives more plasma bombardment than the vertical portion such that horizontal portion and the vertical portion have different etch selectivity, allowing the etching back of the dielectric material 240 with horizontal portion remaining at the bottom of the source/drain trenches 228. Alternatively, the directional deposition process may form the dielectric material 240 with thicker horizontal portions (e.g., on the bottom surface of the source/drain trenches 240) and thinner vertical portions (e.g., on the sidewalls of the gate spacer layer 226), which also allows the horizontal portion remain after the etching back of the dielectric material 240. In some embodiments, the horizontal portion of the dielectric material 240 has a thickness ranging from about 3 nm to about 25 nm, while the vertical portion of the dielectric material 240 has a thinner thickness ranging from about 2 nm to about 8 nm.

Referring to FIGS. 7D and 7E, the deposited dielectric material 240 is then etched back to remove the thinner vertical portions from the sidewalls of the gate spacer layer 226. In some implementations, the etch back operations performed at block 24 may include use of hydrogen fluoride (HF), fluorine gas (F₂), hydrogen (H₂), ammonia (NH₃), nitrogen trifluoride (NF₃), or other fluorine-based etchants. The horizontal portion atop the dummy gate stacks 220 may also be removed due to the loading effect, while the horizontal portion in the bottom of the source/drain trenches 228 is thinned down but still remains as the second dielectric layer 238, which covers the fin base 204 exposed in the source/drain trenches 228. The second dielectric layer 238 may extend between adjacent fin side spacers 226 and over the fin base 204 in the source/drain regions 212SD. In some embodiments, the second dielectric layer 238 has a thickness (measured in Z-direction) in a range from about 3 nm to about 25 nm. The top surface 238a of the second dielectric layer 238 may be above a bottom surface of the bottommost sacrificial layer 206, but lower than a top surface of the bottommost sacrificial layer 206. The bottommost inner spacer 236 may have a height measured in the Z direction from about 5 nm to about 7 nm, such that the second dielectric layer 238 is in physical contact with the bottommost inner spacer 236, while a top portion of the bottommost inner spacer 236 is above the top surface 238a of the second dielectric layer 238. In the depicted embodiment, the top surface 238a of the second dielectric layer 238 has a flat profile. Alternatively, the top surface 238a of the second dielectric layer 238 may have a concave profile or a convex profile. In the depicted embodiment, the top surface 238a of the second dielectric layer 238 is above a top surface 215a of the first dielectric layer 215 under the gate spacer layer 226 by a distance D1 in a range of about 2 nm to about 20 nm. If D1 is too small, the thickness of the second dielectric layer 238 may be too small, and the isolation provided by the second dielectric layer 238 may be too small. If D1 is too large, the thickness of the second dielectric layer 238 may be too large, the top surface of the second dielectric layer 238 may be above the top surface of the bottommost sacrificial layer 206, and a portion of the bottommost channel layer 208 may be blocked by the second dielectric layer 238. In some embodiments, the top surface 238a of the second dielectric layer 238 is above a top surface 215b of the first dielectric layer 215 in the source/drain region areas by a distance D2 in a range of about 3 nm to about 20 nm.

Referring to FIG. 7A, from the top view the first dielectric layer 215 and the second dielectric layers 238 collectively form a strip network pattern. In some embodiments, the first dielectric layers 215 form strips continuously extending along the X-direction and spaced apart from each other along the Y-direction. In some embodiments, the second dielectric layers 238 extend between adjacent strips along the Y-direction and are spaced apart from each other along the X-direction by the gate structure and the gate spacer layers 226.

In some embodiments, the second dielectric layers 238 are formed in n-type transistors only, where only n-type source/drain features are formed over the second dielectric layers 238. In some other embodiments, the second dielectric layers 238 are formed in p-type transistors only, where only p-type source/drain features are formed over the second dielectric layers 238. In yet some other embodiments, the second dielectric layers 238 are formed in both n-type and p-type transistors, where n-type source/drain features and p-type source/drain features are formed over the second dielectric layers 238.

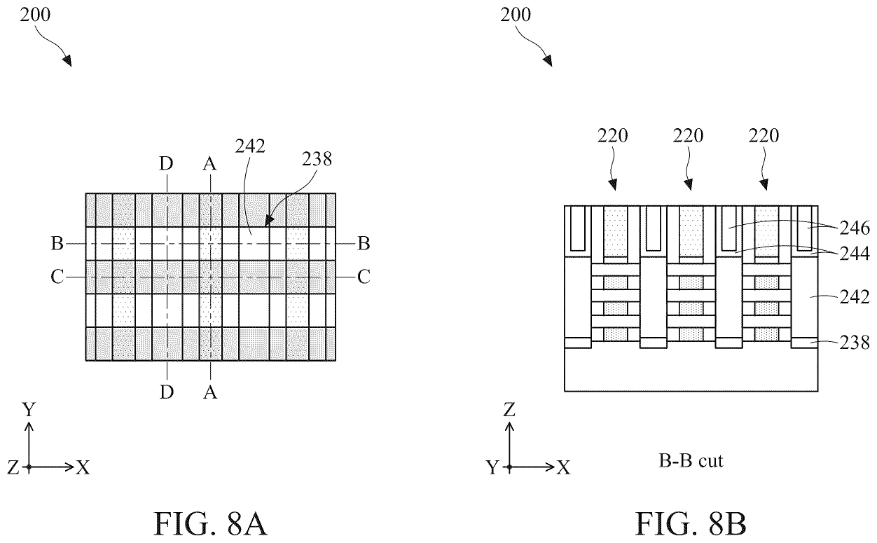

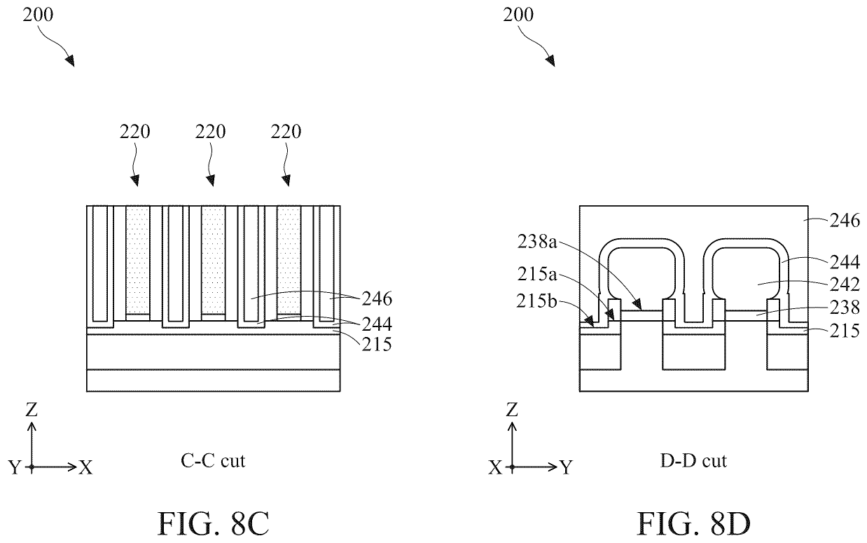

Referring to FIGS. 1 and 8A-8D, method 10 includes a block 26 where source/drain features 242 are formed in the source/drain trenches 228 and over the second dielectric layer 238. FIG. 8A depicts a fragmentary top view of the workpiece 200. FIGS. 8B, 8C, and 8D illustrate fragmentary cross-sectional views of the workpiece 200 taken along line B-B, C-C, and D-D, as shown in FIG. 8A, respectively.

In some embodiments, the source/drain features 242 may be formed using an epitaxial process, such as vapor-phase epitaxy (VPE), ultra-high vacuum CVD (UHV-CVD), molecular beam epitaxy (MBE), and/or other suitable processes. The epitaxial growth process may use gaseous and/or liquid precursors, which interact with the composition of the channel layers 208. The source/drain features 242 may be doped with n-type dopants and/or p-type dopants. Example n-type source/drain features may include Si, GaAs, GaAsP, SiP, or other suitable material and may be in-situ doped during the epitaxial process by introducing an n-type dopant, such as phosphorus (P), arsenic (As), or both. When the source/drain features 242 are not in-situ doped with an n-type dopant, an implantation process (i.e., a junction implant process) may be performed to dope the source/drain features 242 with an n-type dopant. Example p-type source/drain features may include Si, Ge, AlGaAs, SiGe, boron-doped SiGe, or other suitable material and may be in-situ doped during the epitaxial process by introducing a p-type dopant. When the source/drain features 242 are not in-situ doped with a p-type dopant, an implantation process (i.e., a junction implant process) may be performed to dope the source/drain features 242 with a p-type dopant. In some embodiments, the source/drain features 242 include more than one epitaxial semiconductor layer, where the epitaxial semiconductor layers may include the same or different materials and/or the same or different dopant concentrations.

Still referring to FIGS. 1 and 8A-8D, method 10 includes a block 28 where a contact etch stop layer (CESL) 244 is formed over the workpiece 200 and an interlayer dielectric (ILD) layer 246 is formed over the CESL 244.

In some embodiments, the CESL 244 is deposited prior to deposition of the ILD layer 246. In some examples, the CESL 244 includes silicon nitride, silicon oxynitride, and/or other materials known in the art. The CESL 244 may have a different composition from the first dielectric layer 215 and the gate spacer layer 226. The CESL 244 may be formed by ALD, plasma-enhanced chemical vapor deposition (PECVD) process and/or other suitable deposition processes. The ILD layer 246 is then deposited over the CESL 244. In some embodiments, the ILD layer 246 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 246 may be deposited by a PECVD process or other suitable deposition technique. In some embodiments, after formation of the ILD layer 246, the workpiece 200 may be annealed to improve integrity of the ILD layer 246. As shown in FIGS. 8B and 8D, the CESL 244 may be disposed directly on top and side surfaces of the source/drain features 242.

After the deposition of the CESL 244 and the ILD layer 246, the workpiece 200 may be planarized by a planarization process to expose the dummy dielectric layer 216 and the dummy electrode layer 218. For example, the planarization process may include a chemical mechanical planarization (CMP) process. Exposure of the dummy dielectric layer 216 and the dummy electrode layer 218 allows the removal of the dummy gate stacks 220 (to be described below).

Referring to FIGS. 1 and 9A-9F, method 10 includes a block 30 where the dummy gate stacks 220 and the sacrificial layers 206 are replaced with a gate structure 252. FIG. 9A depicts a fragmentary top view of the workpiece 200. FIGS. 9B, 9C, 9D, and 9E illustrate fragmentary cross-sectional views of the workpiece 200 taken along line A-A, B-B, C-C, and D-D, as shown in FIG. 9A, respectively. FIG. 9F is a graph showing levels of surfaces of the workpiece 200.

Operations at block 30 may include removing the dummy gate stacks 220, selectively removing the sacrificial layers 206 between the channel layers 208 in the channel regions 212C, and forming gate structures 252.

In some embodiments, the removal of the dummy gate stacks 220 results in gate trenches over the channel regions 212C. The removal of the dummy gate stacks 220 may include one or more etching processes that are selective to the material of the dummy gate stacks 220. For example, the removal of the dummy gate stacks 220 may be performed using as a selective wet etch, a selective dry etch, or a combination thereof that is selective to the dummy gate stacks 220. After the removal of the dummy gate stacks 220, sidewalls of the channel layers 208 and the sacrificial layers 206 in the channel region 212C are exposed in the gate trenches.

After the removal of the dummy gate stacks 220 to form the gate trenches, operations at block 30 selectively removes the sacrificial layers 206 between the channel layers 208 in the channel region 212C. The selective removal of the sacrificial layers 206 releases the channel layers 208 and may be referred to as a channel release process. The selective removal of the sacrificial layers 206 also leave behind space between adjacent channel layers 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

In some embodiments, the gate structures 252 are then formed. Operations at block 30 may further include forming the gate structures 252 to wrap around each of the channel layers 208. In some embodiments, the gate structures 252 are formed within the gate trenches and into the space left behind by the removal of the sacrificial layers 206. The gate structure 252 includes a gate dielectric layer 254 and a gate electrode layer 256 over the gate dielectric layer 254. In some embodiments, while not explicitly shown in the figures, the gate dielectric layer 254 includes an interfacial layer disposed on the channel layers 208 and a high-K gate dielectric layer over the interfacial layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO2), hafnium zirconium oxide (HfZrO), tantalum oxide (Ta₂O₅), hafnium silicon oxide (HfSiO4), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO3 (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 256 of the gate structure 252 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 256 may include titanium nitride (TIN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 256 may be formed by ALD, PVD, CVD, e-beam evaporation, or other suitable process. In various embodiments, a CMP process may be performed to remove excessive metal, thereby providing a substantially planar top surface of the gate structure 252.

Referring to FIG. 9D, in some embodiments, the removal of the dummy gate stack 220 and the sacrificial layers 206 also removes a portion of the first dielectric layer 215 in the gate trench. In such embodiments, a top surface 215c under the gate structure 252 is lower than the top surface 215a under the gate spacer layer 226. In some embodiments, the first dielectric layer 215 under the dummy gate stacks 220 before forming the gate trench protects the isolation features 214 therebelow from being etched, thus, loss of isolation features 214 is avoided. In other words, deep gate structures extending into the isolation features 214 are avoided, and the gate structures 252 stop in the first dielectric layer 215 and are shallower than the deeps gate structures. Thus, parasitic capacitance from deep gate structures may be mitigated.

FIG. 9F illustrates levels (i.e., horizontal levels perpendicular to the Z-direction) of surfaces of the workpiece 200. The surfaces of the workpiece 200 may not be in a same cross-sectional view, thus only the levels of the surfaces with respect to a bottom surface 215d of the first dielectric layer 215 are shown in FIG. 9F. Dashed lines 238a′, 215a′, 215b′, and 215c′ illustrate levels of the top surfaces 238a, 215a, 215b, and 215c, respectively. For the purpose of clarity, FIG. 9F is enlarged compared to FIGS. 9D and 9E. In the depicted embodiment, the top surface 238a of the second dielectric layer 238 is above the top surface 215a of the first dielectric layer 215, which is above the top surface 215c of the first dielectric layer 215, which is above the top surface 215b of the first dielectric layer 215. As described with reference to FIG. 7E, the top surfaces 215a and 215b have vertical distances D1 and D2, respectively, from the top surface 238a. The top surface 215c has a vertical distance D3 from the top surface 238a. In some embodiments, D2 is greater than D3, and D3 is greater than D1. The first dielectric layer 215 has thicknesses T1, T2, and T3 measured from the bottom surface 215d to the top surfaces 215a, 215b, and 215c, respectively. In some embodiments, T1 is greater than T3 and T3 is greater than T2. T1 may be greater than T3 by about 1 nm to about 5 nm. In embodiments, a sum of T1 and D1 is about the same as a sum of T2 and D2, and is about the same as a sum of T3 and D3. The thicknesses T1, T2, and T3 may be achieved by controlling the operations (e.g., etching processes) in blocks 20 and 30.

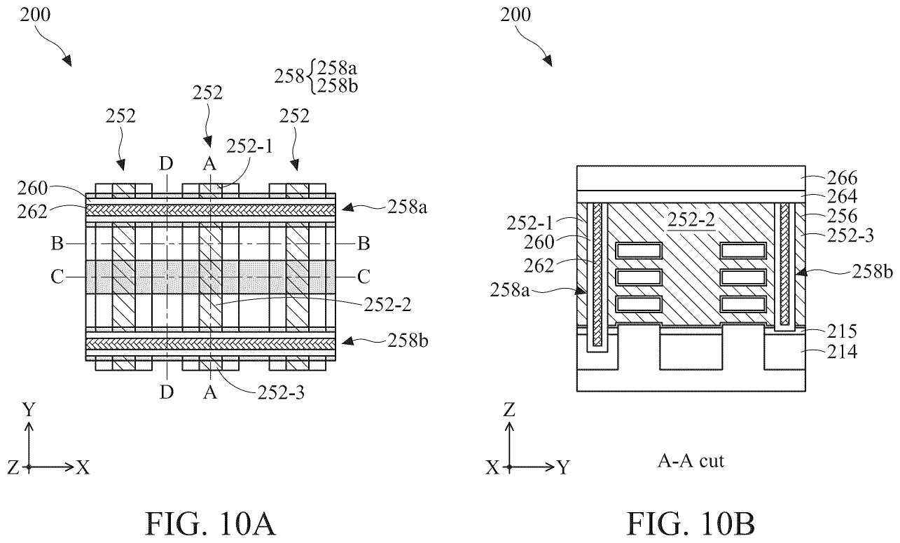

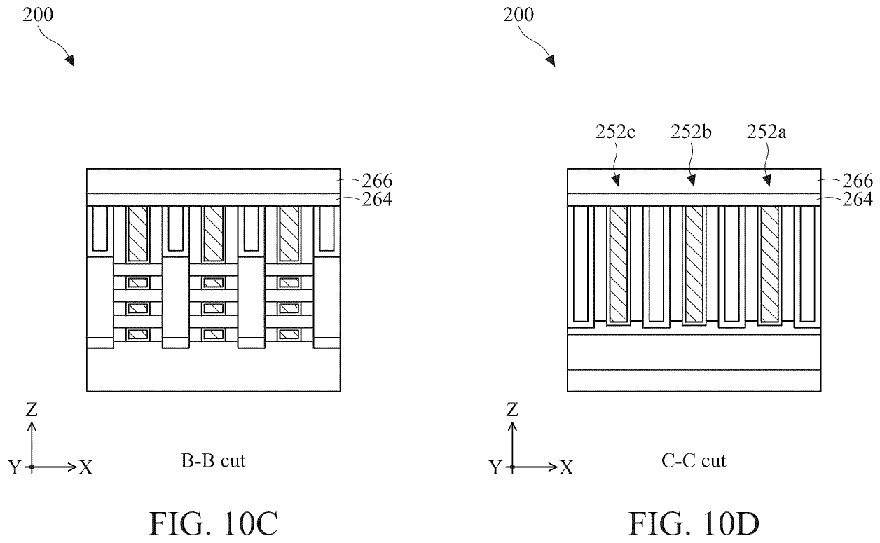

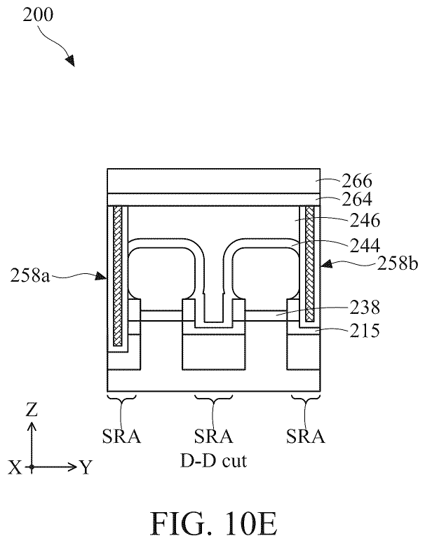

Referring to FIGS. 1 and 10A-10E, method 10 includes a block 32 where gate isolation structures are formed to cut the metal gate structures 252 into pieces. FIG. 10A depicts a fragmentary top view of the workpiece 200. FIGS. 10B, 10C, 10D, and 10E illustrate fragmentary cross-sectional views of the workpiece 200 taken along line A-A, B-B, C-C, and D-D, as shown in FIG. 10A, respectively.

In an example process, gate isolation trenches are formed to cut the continuous metal gate structures 252 into pieces. The gate isolation structures 258 are formed in the gate isolation trenches. The formation of the gate isolation structures 258 may further include conformally depositing a first dielectric material 260 over the structure and depositing a second dielectric material 262 to fill remaining portions of the gate isolation trenches, and performing a planarization process to the workpiece 200 to remove excess materials over the metal gate structures 252. The gate isolation structure 258 may contact a sidewall of the adjacent fin side spacer 226 and a sidewall of the first dielectric layer 215 therebelow. In some embodiments, the gate isolation structure 258 extends through the metal gate structures 252 and the first dielectric layer 215, and into the isolation feature 214, such as the depicted gate isolation structure 258a. In such embodiments, the gate isolation structure 258 extends through the ILD layer 246, the CESL 244, and the first dielectric layer 215, and into the isolation feature 214 in the source/drain region area SRA. In some other embodiments, the gate isolation structure 258 extends through the metal gate structures 252 and into the first dielectric layer 215, but does not extend into the isolation feature 214, such as the depicted gate isolation structure 258b. In such embodiments, the gate isolation structure 258 extends through the ILD layer 246 and the CESL 244, and into the first dielectric layer 215, but does not extend into the isolation feature 214 in the source/drain region area SRA. The gate isolation structure 258a and the gate isolation structure 258b can be separately or collectively referred to as gate isolation structure(s) 258. The numbers and positions of the gate isolation structures 258a and 258b shown in FIGS. 10A-10E are for illustration and example purpose only and should not be construed as limiting the scope of the present disclosure. In an embodiment, each of the first dielectric material 260 and the second dielectric material 262 may include silicon oxide, silicon nitride, silicon carbide, silicon oxynitride, silicon oxycarbide, silicon carbonitride, a low-k dielectric material, other suitable materials, or combinations thereof, and may be deposited by CVD, PECVD, flowable CVD, PVD, ALD, other suitable methods, or combinations thereof.

In the depicted embodiment, the gate isolation structures 258 cut the metal gate structures 252 into electrically and physically isolated segments (e.g., segments 252-1, 252-2, and 252-3). The workpiece 200 may also include additional gate isolation structures. In some embodiments, the gate isolation structures 258 may be referred to as cut metal gates (CMGs).

Still referring to FIGS. 1 and 10A-10E, method 10 includes a block 34 where further processes are formed to complete the fabrication of the workpiece 200. Such further processes may include, for example, depositing a contact etch stop layer (CESL) 264 over the workpiece 200 and depositing an interlayer dielectric (ILD) layer 266 over the CESL 264. Forming the CESL 264 and the ILD layer 246 may use any suitable methods. The CESL 264 may include similar materials and be formed using similar methods as the CESL 244. The ILD layer 266 may include similar materials and be formed using similar methods as the ILD layer 246.

Other further processes may form contact openings, contact metal, as well as various contacts/vias/lines and multilayer interconnect features (e.g., metal layers and interlayer dielectrics), configured to connect the various features to form a functional circuit that may include one or more multi-gate devices. The various interconnection features may employ various conductive materials including copper, tungsten, and/or silicide. In one example, a damascene and/or dual damascene process is used to form a copper related multilayer interconnection structure.

Referring to FIGS. 1 and 11A-18, alternative embodiments of the workpiece 200 at various stages of fabrication according to embodiments of method 10 are described below.

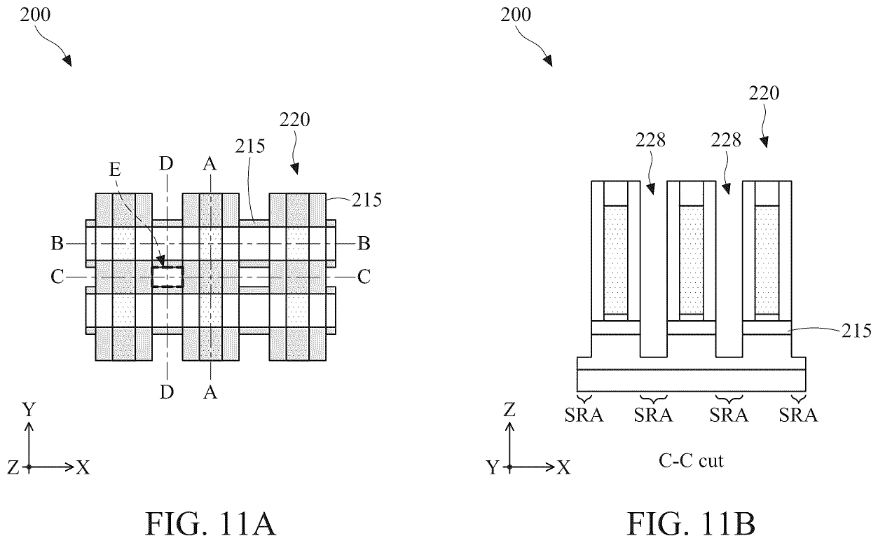

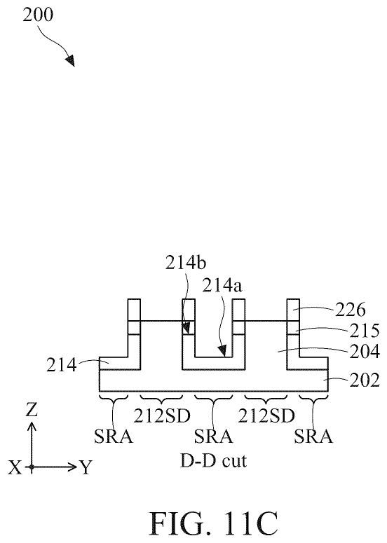

In some embodiments, operations at block 20 of method 10 produces an alternative structure as shown in FIG. 11A, which depicts a fragmentary top view of the workpiece 200. FIGS. 11B and 11C illustrate fragmentary cross-sectional views of the workpiece 200 taken along line C-C and D-D, as shown in FIG. 11A, respectively. Fragmentary cross-sectional views of the workpiece 200 taken along line A-A and B-B as shown in FIG. 11A are similar to FIGS. 5B and 5C, respectively.

As compared to the embodiments illustrated in FIGS. 5A-5E, referring to FIGS. 11A-11C, differences include the following. First, the first dielectric layer 215 in the source/drain region areas SRA (e.g., the area E) are completely removed. Second, in some embodiments, without the protection by the first dielectric layer 215, a portion of the isolation feature 214 in the source/drain region areas SRA is removed. Thus, the isolation feature 214 may have a first top surface 214a exposed in the source/drain region areas SRA and a second top surface 214b adjacent to the fin base 204. The first top surface 214a may be below the second top surface 214b. In the depicted embodiments, similar to FIG. 5E, the fin side spacer 226 remains on two sides of the fin base 204 in the source/drain regions 212SD. In such embodiments, the second top surface 214b is under the fin side spacer 226.

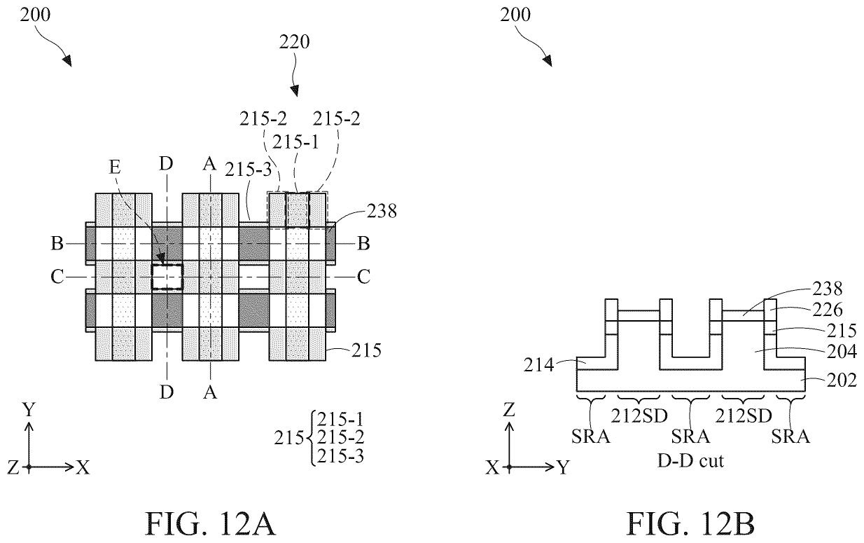

The procedure moves on to process the workpiece 200 according to block 22 of method 10, as illustrated in FIGS. 12A-12B. FIG. 12A depicts a fragmentary top view of the workpiece 200 and FIG. 12B depicts a fragmentary cross-sectional view of the workpiece 200 taken along line D-D as shown in FIG. 12A. Similar as described above, the second dielectric layer 238 is formed over the fin base 204 in the source/drain regions 212SD. As depicted in FIG. 12A, the first dielectric layers 215 include first portions 215-1 under the gate structures 252, second portions 215-2 under the gate spacer layer 226 along sidewalls of the gate structures 252, and a third portion 215-3 under the fin side spacers 226. In the depicted embodiments, the first dielectric layers 215 and the second dielectric layers 238 collectively form a first checkerboard pattern. In the first checkerboard pattern, the first portions 215-1 and the second portions 215-2 of the first dielectric layers 215 form a first row along the X-direction, the second dielectric layers 238 and the third portions 215-3 form a second row along the X-direction. The first row and the second row have overlaps along the X-direction because of the third portions 215-3. Following rows (e.g., a third row, a fourth row) along the X-direction repeat the first row and the second row.

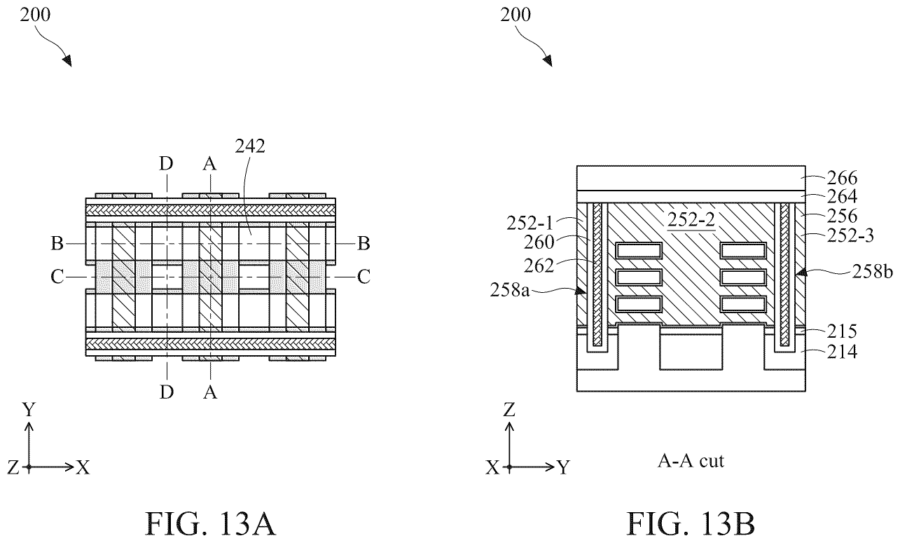

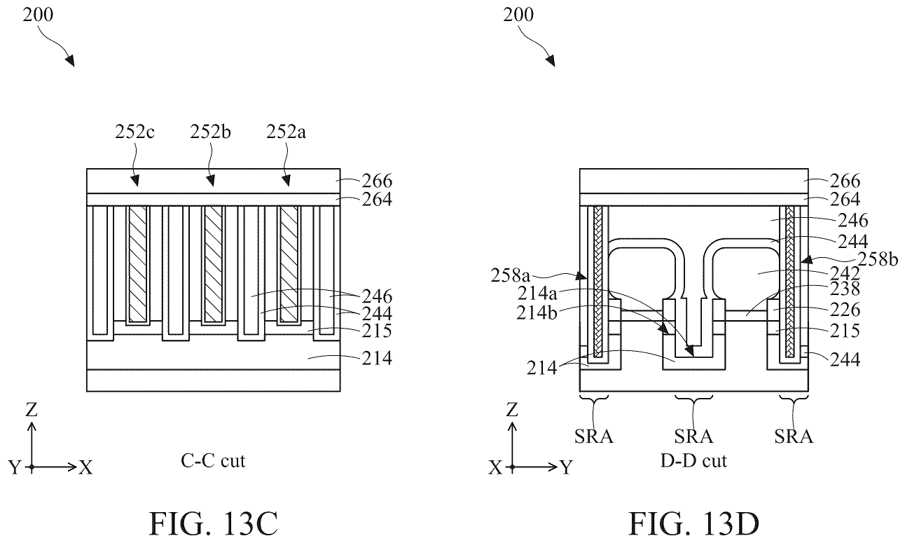

The procedure moves on to process the workpiece 200 according to blocks 24-34 of method 10. FIG. 13A depicts a fragmentary top view of the workpiece 200 at block 34. FIGS. 13B, 13C, and 13D illustrate fragmentary cross-sectional views of the workpiece 200 taken along line A-A, C-C and D-D as shown in FIG. 13A, respectively. A fragmentary cross-sectional view of the workpiece 200 taken along line B-B as shown in FIG. 13A is similar to FIG. 10C.

As compared to the embodiments illustrated in FIGS. 10A-10E, referring to FIGS. 13B-13D, differences include the following. First, there is no first dielectric layer 215 in the source/drain region areas SRA. Second, the CESL 244 extends into the isolation feature 214, and a portion of the ILD layer 246 may be disposed between the first dielectric layer 215. The CESL 244 may extend to below the bottom surface of the first dielectric layer 215. The portion of the ILD layer 246 may extend to below the bottom surface of the first dielectric layer 215. Third, in such embodiments, the gate isolation structures 258 extend through the ILD layer 246 and CESL 244 and extend into the isolation features 214 in the source/drain region areas SRA. The gate isolation structures 258 do not extend into the first dielectric layer 215 as the gate isolation structure 258b depicted in FIGS. 10B and 10E.

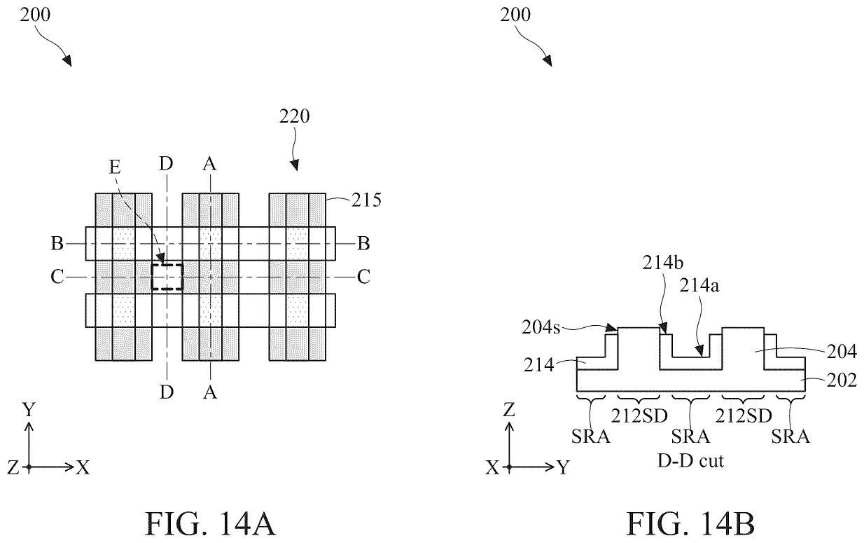

In some embodiments, operations at block 20 of method 10 produces another alternative structure as shown in FIG. 14A, which depicts a fragmentary top view of the workpiece 200. FIG. 14B illustrates a fragmentary cross-sectional view of the workpiece 200 taken along line D-D as shown in FIG. 14A. Fragmentary cross-sectional views of the workpiece 200 taken along line A-A, B-B, and C-C as shown in FIG. 14A are similar to FIGS. 5B, 5C, and 11B, respectively.

As compared to the embodiments illustrated in FIGS. 11A-11C, referring to FIGS. 14A-14B, differences include the following. The fin side spacers 226 and the first dielectric layer 215 below the fin side spacers 226 are removed in the operations of block 20. In such embodiments, the top surface 214b of the isolation feature 214 and a portion of sidewalls 204s of the fin base 204 are exposed.

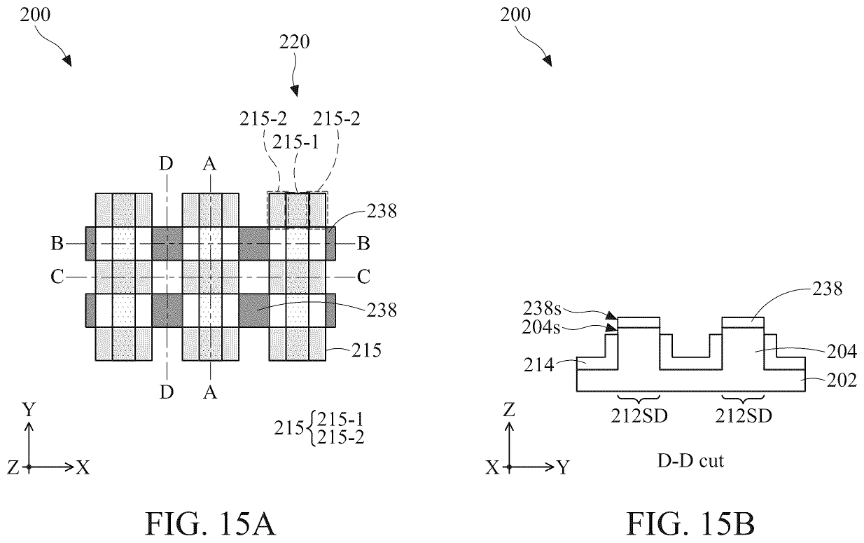

The procedure moves on to process the workpiece 200 according to block 22 of method 10, as illustrated in FIGS. 15A-15B. FIG. 15A depicts a fragmentary top view of the workpiece 200 and FIG. 15B depicts a fragmentary cross-sectional view of the workpiece 200 taken along line D-D as shown in FIG. 15A. Similar as described above, the second dielectric layer 238 is formed over the fin base 204 in the source/drain regions 212SD. As depicted in FIG. 15A, the first dielectric layers 215 include first portions 215-1 under the gate structures 252 and second portions 215-2 under the gate spacer layer 226 along sidewalls of the gate structures 252. In the depicted embodiments, the first dielectric layers 215 and the second dielectric layers 238 collectively form a second checkerboard pattern. As compared to the embodiments illustrated in FIGS. 12A-12B, referring to FIGS. 15A-15B, differences include the following. First, the first dielectric layers 215 does not include third portions 215-3. In the second checkerboard pattern, the first portions 215-1 and the second portions 215-2 of the first dielectric layers 215 form a first row along the X-direction, the second dielectric layers 238 form a second row along the X-direction. The first row and the second row do not have overlaps along the X-direction. Following rows (e.g., a third row, a fourth row) along the X-direction repeat the first row and the second row. Second, sidewalls 238s of the first dielectric layer 215 and a portion of the sidewalls 204s of the fin base 204 in the source/drain region 212SD are exposed.

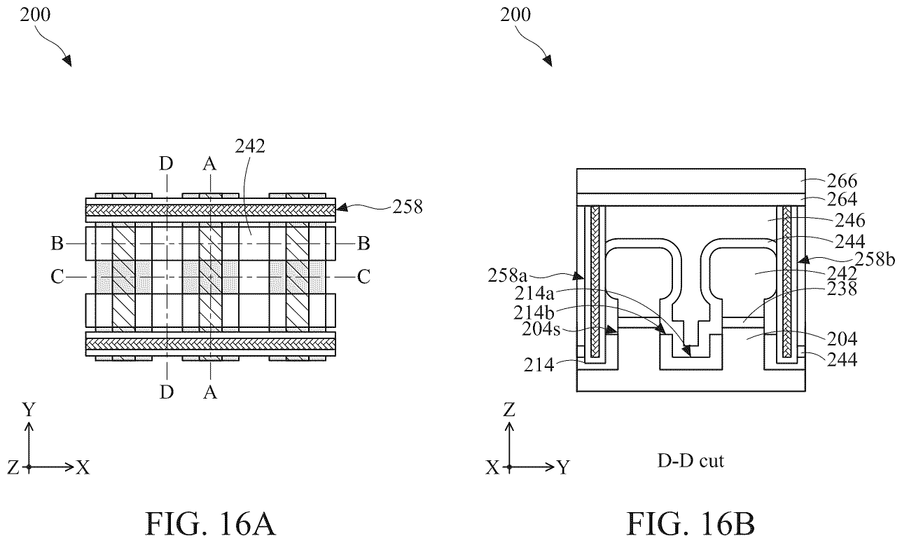

The procedure moves on to process the workpiece 200 according to blocks 24-34 of method 10. FIG. 16A depicts a fragmentary top view of the workpiece 200 at block 34. FIG. 16B illustrates a fragmentary cross-sectional view of the workpiece 200 taken along line D-D as shown in FIG. 16A. Fragmentary cross-sectional views of the workpiece 200 taken along line A-A, B-B, and C-C as shown in FIG. 16A are similar to FIGS. 13B, 10C, and 13C, respectively.

As compared to the embodiments illustrated in FIGS. 13A-13D, referring to FIGS. 16A-16B, differences include the following. First, the workpiece 200 does not include fin side spacers 226 or a first dielectric layer 215 on sides of the fin base 204. Second, the CESL 244 may be disposed on the top surface 214b of the isolation feature 214, a portion of sidewalls 204s of the fin base 204, and sidewalls of the second dielectric layer 238.

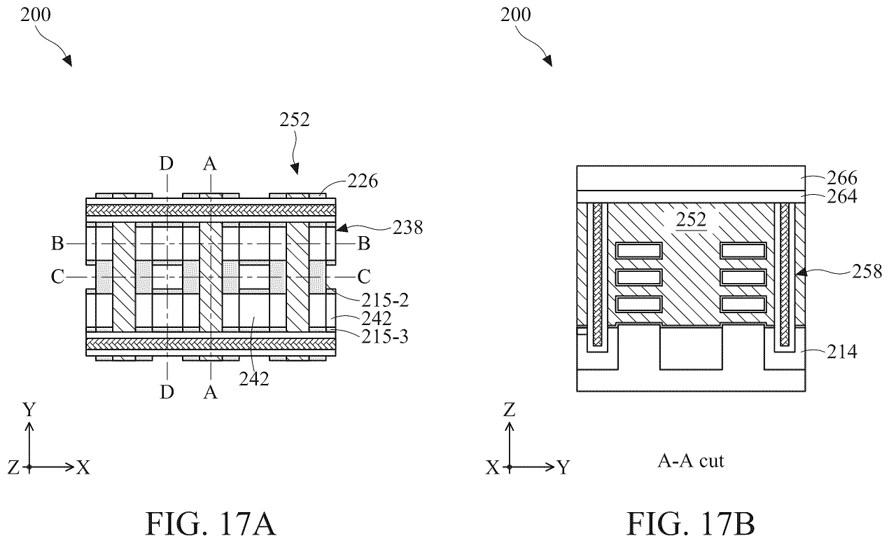

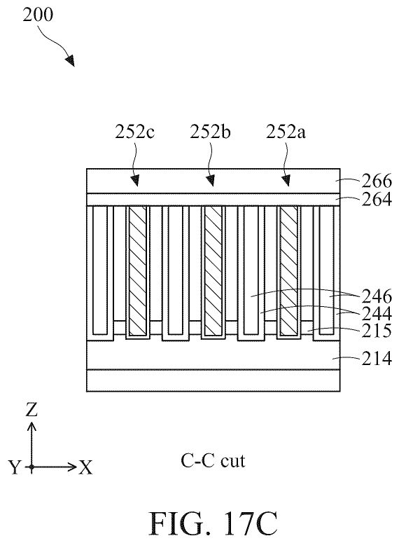

In some embodiments, operations at block 30 of method 10 produces yet another alternative structure as shown in FIG. 17A, which depicts a fragmentary top view of the workpiece 200 at block 34 of method 10. FIGS. 17B-17C illustrate fragmentary cross-sectional views of the workpiece 200 taken along line A-A and C-C as shown in FIG. 17A. Fragmentary cross-sectional views of the workpiece 200 taken along line B-B and D-D as shown in FIG. 17A are similar to FIGS. 10C and 13D, respectively.

As compared to the embodiments illustrated in FIGS. 13A-13D, referring to FIGS. 17A-17C, differences include the following. First, in some embodiments, the first dielectric layer 215 includes the second portions 215-2 and the third portions 215-3 under the gate spacer layers 226, but does not include a first portion 215-1 under the gate structures 252. This may result from operations of block 30 (e.g., removing the dummy gate stack 220), which additionally remove the first dielectric layer 215 under the dummy gate stack 220. In some embodiments, a top layer of the isolation feature 214 in the gate trenches is also removed. In other words, the gate structure 252 extends into the isolation feature 214 as depicted in FIGS. 17B and 17C. During the etching processes to form the gate trenches at block 30, an etch rate to the first dielectric layer 215 is less than an etch rate to the isolation feature 214. Thus, the first dielectric layer 215 under the dummy gate stack 220 slows down the etching processes to form the gate trenches. By having the protection by the first dielectric layer 215 under the dummy gate stack 220, loss of isolation features 214 may be reduced and more isolation features 214 may remain in the gate trenches. In other words, the gate structure 252 may be shallower and extending less into the isolation feature 214 in the depicted embodiments, compared to when there is no first dielectric layer under the dummy gate stack 220 before forming the gate trench. Therefore, deep gate structures are mitigated and parasitic capacitance from deep gate structures (e.g., from a portion of the gate structure extended into the isolation feature 214) may be avoided or reduced. Second, from the top view in FIG. 17A, the second portions 215-2 and the third portions 215-3 of the first dielectric layer 215 and the second dielectric layer 238 (overlapping with the source/drain features 242) collectively form a third checkerboard pattern. In the third checkerboard pattern, the second portions 215-2 of the first dielectric layers 215 form a first row along the X-direction, the second dielectric layers 238 and the third portion 215-3 of the first dielectric layers 215 form a second row along the X-direction. The first row and the second row have overlaps along the X-direction because of the third portions 215-3. Following rows (e.g., a third row, a fourth row) along the X-direction repeat the first row and the second row. The third checkerboard pattern is discontinuous in the X-direction because of lacking of the first portion 215-1 of the first dielectric layers 215.

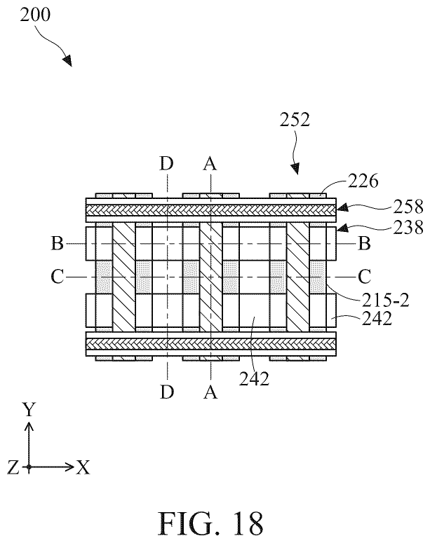

In some embodiments, operations at block 30 of method 10 produces yet another alternative structure as shown in FIG. 18, which depicts a fragmentary top view of the workpiece 200 at block 34 of method 10. Fragmentary cross-sectional views of the workpiece 200 taken along line A-A, B-B, C-C, and D-D as shown in FIG. 18 are similar to FIGS. 17B, 10C, 17C, and 16B, respectively.

As compared to the embodiments illustrated in FIGS. 17A-17C, referring to FIG. 18, differences include the following. First, the workpiece 200 does not include fin side spacers 226 or a first dielectric layer 215 on sides of the fin base 204. Second, the CESL 244 may be disposed on the top surface 214b of the isolation feature 214, a portion of sidewalls 204s of the fin base 204, and sidewalls of the second dielectric layer 238. Third, the first dielectric layer 215 includes the second portions 215-2 below the gate spacer layers 226 along sidewalls of the gates structures 252 but not first portions 215-1 or third portions 215-3. From the top view in FIG. 18, the second portions 215-2 of the first dielectric layer 215 and the second dielectric layer 238 (overlapping with the source/drain features 242) collectively form a fourth checkerboard pattern. In the fourth checkerboard pattern, the second portions 215-2 of the first dielectric layers 215 form a first row along the X-direction, and the second dielectric layers 238 form a second row along the X-direction. The first row and the second row do not have overlaps along the X-direction. Following rows (e.g., a third row, a fourth row) along the X-direction repeat the first row and the second row. The fourth checkerboard pattern is discontinuous in the X-direction because of lacking of the first portion 215-1 of the first dielectric layers 215.

One of ordinary skill may recognize although FIGS. 2A-18 illustrate GAA devices as embodiments, other examples of semiconductor devices may benefit from aspects of the present disclosure, such as FinFET devices.

Although not intended to be limiting, one or more embodiments of the present disclosure provide many benefits to a semiconductor device. For example, the present disclosure mitigates parasitic capacitance and current leakage from a mesa and mitigates isolation feature loss when forming gate trenches by including bottom isolations (e.g., the first dielectric layer and the second dielectric layer) disclosed herein. Forming of deep gate structure and associated parasitic capacitance may also be mitigated. Thus, the overall performance of the semiconductor device may be improved.

In one exemplary aspect, the present disclosure is directed to a semiconductor structure. The semiconductor structure includes a semiconductor fin-shaped structure protruding from a substrate and including a fin base and a stack of channel layers over a first portion of the fin base, an isolation feature disposed adjacent to the fin base, a first dielectric layer disposed over the isolation feature, a metal gate structure wrapping around the stack of channel layers, a gate spacer disposed over the isolation feature and along a sidewall of the metal gate structure, a second dielectric layer disposed over a second portion of the fin base and adjacent to the stack of channel layers, and a source/drain feature disposed over the second dielectric layer and connected to the stack of channel layers. The fin base rises above the isolation feature. The metal gate structure and the gate spacer are disposed over a portion of the first dielectric layer. From a top view, the first dielectric layer and the second dielectric layer form a checkerboard pattern or a strip network pattern.

In some embodiments, the first dielectric layer has a first thickness below the metal gate structure and a second thickness below the gate spacer, and the first thickness is smaller than the second thickness by about 1 nm to about 5 nm. In some embodiments, the semiconductor structure further includes an etch stop layer (ESL) disposed over the first dielectric layer, and the first dielectric layer has a third thickness below the ESL and smaller than the first thickness. In some embodiments, the semiconductor structure further includes an etch stop layer (ESL) disposed over the isolation feature, and the ESL extends to below a bottom surface of the first dielectric layer. In some embodiments, the semiconductor structure further includes a fin spacer disposed along a sidewall of the second dielectric layer and over the first dielectric layer. In some embodiments, a top surface of the first dielectric layer below the gate spacer is below a top surface of the second dielectric layer. In some embodiments, the semiconductor structure further includes a gate isolation structure on an end of the metal gate structure, and the gate isolation structure extends through the first dielectric layer. In some embodiments, the first dielectric layer, the second dielectric layer, and the isolation feature include different compositions.

In another exemplary aspect, the present disclosure is directed to a semiconductor structure. The semiconductor structure includes a first fin-shaped structure and a second fin-shaped structure adjacent to the first fin-shaped structure. The first fin-shaped structure and the second fin-shaped structure protrude from a substrate and extend lengthwise along a first direction. The first fin-shaped structure includes a first fin base and a first stack of channel layers over the first fin base. The second fin-shaped structure includes a second fin base and a second stack of channel layers over the second fin base. The semiconductor structure further includes an isolation feature disposed between the first fin base and the second fin base, a first dielectric layer disposed over the isolation feature, a metal gate structure disposed over and wrapping around each channel layer of the first stack of channel layers and the second stack of channel layers and extending lengthwise along a second direction perpendicular to the first direction, a gate spacer disposed over the first dielectric layer and along a sidewall of the metal gate structure, a first source/drain feature disposed over the first fin base and connected to the first stack of channel layers, a second source/drain feature disposed over the second fin base and connected to the second stack of channel layers, and second dielectric layers disposed between the first source/drain feature and the first fin base and between the second source/drain feature and the second fin base. From a top view, the first dielectric layer and the second dielectric layers form a checkerboard pattern or a strip network pattern.

In some embodiments, a top surface of the second dielectric layers is above a top surface of the first dielectric layer interfacing the gate spacer. In some embodiments, a portion of the first dielectric layer is disposed between the metal gate structure and the isolation feature. In some embodiments, the semiconductor structure further includes an etch stop layer (ESL) disposed over the isolation feature and between the first source/drain feature and the second source/drain feature, and a portion of the first dielectric layer is disposed between the ESL and the isolation feature. In some embodiments, the first dielectric layer includes silicon nitride, the isolation feature includes silicon oxide, and the second dielectric layers include silicon oxynitride. In some embodiments, the semiconductor structure further includes a third source/drain feature disposed over the first fin base and connected to the first stack of channel layers, and a fourth source/drain feature disposed over the second fin base and connected to the second stack of channel layers. The second dielectric layers are further disposed between the third source/drain feature and the first fin base and between the fourth source/drain feature and the second fin base, and from the top view, the first dielectric layer and the second dielectric layers form the checkerboard pattern. In some embodiments, the semiconductor structure further includes a fin spacer disposed along a sidewall of the second dielectric layers and over a portion of the first dielectric layer. In some embodiments, the semiconductor structure further includes a gate isolation structure on an end of the metal gate structure, and the gate isolation structure is disposed on a portion of the first dielectric layer.

In yet another exemplary aspect, the present disclosure is directed to a method. The method includes providing a workpiece. The workpiece includes a first active region and a second active region protruding from a substrate, and a shallow trench isolation (STI) between the first active region and the second active region. The first active region and the second active region each include a source/drain region and a channel region adjacent to the source/drain region. The first active region and the second active region extend lengthwise along a first direction. The method further includes forming a first dielectric layer over the STI, forming a dummy gate extending lengthwise along a second direction and over the channel regions of the first active region and the second active region and the STI, the second direction being perpendicular to the first direction, forming a gate spacer layer over the workpiece, and forming source/drain openings in the source/drain regions of the first active region and the second active region. A first portion of the first dielectric layer below the gate spacer layer and the dummy gate remains. The method further includes forming a second dielectric layer in the source/drain openings. From a top view, the first dielectric layer and the second dielectric layer form a checkerboard pattern or a strip network pattern. The method further includes forming source/drain features over the second dielectric layer and in the source/drain openings, and replacing the dummy gate with a metal gate structure.

In some embodiments, replacing the dummy gate with the metal gate structure includes removing the dummy gate and a top part of a second portion of the first dielectric layer below the dummy gate to form a gate opening, and forming the metal gate structure in the gate opening. In some embodiments, the method further includes forming a gate isolation structure to cut the metal gate structure into two segments, and the gate isolation structure extends through the first dielectric layer. In some embodiments, forming the source/drain openings includes recessing the source/drain regions, the gate spacer layer over the source/drain regions, and the STI between the source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor fin-shaped structure protruding from a substrate and including a fin base and a stack of channel layers over a first portion of the fin base;
an isolation feature disposed adjacent to the fin base, wherein the fin base rises above the isolation feature;
a first dielectric layer disposed over the isolation feature;
a metal gate structure wrapping around the stack of channel layers;
a gate spacer disposed over the isolation feature and along a sidewall of the metal gate structure, wherein the metal gate structure and the gate spacer are disposed over a portion of the first dielectric layer;
a second dielectric layer disposed over a second portion of the fin base and adjacent to the stack of channel layers, wherein from a top view, the first dielectric layer and the second dielectric layer form a checkerboard pattern or a strip network pattern; and
a source/drain feature disposed over the second dielectric layer and connected to the stack of channel layers.

2. The semiconductor structure of claim 1, wherein the first dielectric layer has a first thickness below the metal gate structure and a second thickness below the gate spacer, and
wherein the first thickness is smaller than the second thickness by about 1 nm to about 5 nm.

3. The semiconductor structure of claim 2, further comprising an etch stop layer (ESL) disposed over the first dielectric layer,
wherein the first dielectric layer has a third thickness below the ESL and smaller than the first thickness.

4. The semiconductor structure of claim 1, further comprising an etch stop layer (ESL) disposed over the isolation feature,
wherein the ESL extends to below a bottom surface of the first dielectric layer.

5. The semiconductor structure of claim 1, further comprising a fin spacer disposed along a sidewall of the second dielectric layer and over the first dielectric layer.

6. The semiconductor structure of claim 1, wherein a top surface of the first dielectric layer below the gate spacer is below a top surface of the second dielectric layer.

7. The semiconductor structure of claim 1, further comprising a gate isolation structure on an end of the metal gate structure,
wherein the gate isolation structure extends through the first dielectric layer.

8. The semiconductor structure of claim 1, wherein the first dielectric layer, the second dielectric layer, and the isolation feature include different compositions.

9. A semiconductor structure, comprising:
a first fin-shaped structure and a second fin-shaped structure adjacent to the first fin-shaped structure, wherein the first fin-shaped structure and the second fin-shaped structure protrude from a substrate and extend lengthwise along a first direction, wherein the first fin-shaped structure includes a first fin base and a first stack of channel layers over the first fin base, wherein the second fin-shaped structure includes a second fin base and a second stack of channel layers over the second fin base;
an isolation feature disposed between the first fin base and the second fin base;
a first dielectric layer disposed over the isolation feature;
a metal gate structure disposed over and wrapping around each channel layer of the first stack of channel layers and the second stack of channel layers and extending lengthwise along a second direction perpendicular to the first direction;
a gate spacer disposed over the first dielectric layer and along a sidewall of the metal gate structure;
a first source/drain feature disposed over the first fin base and connected to the first stack of channel layers;
a second source/drain feature disposed over the second fin base and connected to the second stack of channel layers; and
second dielectric layers disposed between the first source/drain feature and the first fin base and between the second source/drain feature and the second fin base, wherein from a top view, the first dielectric layer and the second dielectric layers form a checkerboard pattern or a strip network pattern.

10. The semiconductor structure of claim 9, wherein a top surface of the second dielectric layers is above a top surface of the first dielectric layer interfacing the gate spacer.

11. The semiconductor structure of claim 9, wherein a portion of the first dielectric layer is disposed between the metal gate structure and the isolation feature.

12. The semiconductor structure of claim 9, further comprising an etch stop layer (ESL) disposed over the isolation feature and between the first source/drain feature and the second source/drain feature,
wherein a portion of the first dielectric layer is disposed between the ESL and the isolation feature.

13. The semiconductor structure of claim 9, wherein the first dielectric layer includes silicon nitride, the isolation feature includes silicon oxide, and the second dielectric layers include silicon oxynitride.

14. The semiconductor structure of claim 9, further comprising:
a third source/drain feature disposed over the first fin base and connected to the first stack of channel layers; and
a fourth source/drain feature disposed over the second fin base and connected to the second stack of channel layers,
wherein the second dielectric layers are further disposed between the third source/drain feature and the first fin base and between the fourth source/drain feature and the second fin base,
wherein from the top view, the first dielectric layer and the second dielectric layers form the checkerboard pattern.

15. The semiconductor structure of claim 9, further comprising a fin spacer disposed along a sidewall of the second dielectric layers and over a portion of the first dielectric layer.

16. The semiconductor structure of claim 9, further comprising a gate isolation structure on an end of the metal gate structure,
wherein the gate isolation structure is disposed on a portion of the first dielectric layer.

17. A method, comprising:
providing a workpiece including a first active region and a second active region protruding from a substrate, and a shallow trench isolation (STI) between the first active region and the second active region, wherein the first active region and the second active region each include a source/drain region and a channel region adjacent to the source/drain region, and wherein the first active region and the second active region extend lengthwise along a first direction;
forming a first dielectric layer over the STI;
forming a dummy gate extending lengthwise along a second direction and over the channel regions of the first active region and the second active region and the STI, the second direction being perpendicular to the first direction;
forming a gate spacer layer over the workpiece;
forming source/drain openings in the source/drain regions of the first active region and the second active region, wherein a first portion of the first dielectric layer below the gate spacer layer and the dummy gate remains;
forming a second dielectric layer in the source/drain openings, wherein from a top view, the first dielectric layer and the second dielectric layer form a checkerboard pattern or a strip network pattern;
forming source/drain features over the second dielectric layer and in the source/drain openings; and
replacing the dummy gate with a metal gate structure.

18. The method of claim 17, wherein replacing the dummy gate with the metal gate structure includes:
removing the dummy gate and a top part of a second portion of the first dielectric layer below the dummy gate to form a gate opening, and
forming the metal gate structure in the gate opening.

19. The method of claim 17, forming comprising forming a gate isolation structure to cut the metal gate structure into two segments,
wherein the gate isolation structure extends through the first dielectric layer.

20. The method of claim 17, wherein forming the source/drain openings includes recessing the source/drain regions, the gate spacer layer over the source/drain regions, and the STI between the source/drain regions.
